(19) United States
(12) Patent Application Publication
(10) Pub. No.: US 2025/0056910 A1
(43) Pub. Date: Feb. 13, 2025

(54) IMAGING ELEMENT, METHOD FOR MANUFACTURING IMAGING ELEMENT, AND ELECTRONIC DEVICE

(71) Applicant: SONY SEMICONDUCTOR SOLUTIONS CORPORATION, KANAGAWA (JP)

(72) Inventors: MASATAKA ISHIDA, KUMAMOTO (JP); HARUMI TANAKA, KANAGAWA (JP)

(21) Appl. No.: 18/718,507

(22) PCT Filed: Oct. 24, 2022
(86) PCT No.: PCT/JP2022/039480

§ 371 Date: Jun. 11, 2024

(30) Foreign Application Priority Data
Dec. 20, 2021 (JP) 2021-206410

(51) Int. Cl. H01L 27/146; H04N 25/532; H04N 25/62; H04N 25/77

(52) U.S. Cl. CPC H01L 27/14623; H01L 27/14612; H01L 27/1464; H01L 27/14643; H01L 27/14689; H04N 25/532; H04N 25/62; H04N 25/77

(57) ABSTRACT

[Problem] To provide an imaging element in which generation of optical noise is suppressed.
[Solution] An imaging element 10 includes a semiconductor substrate 101, a photoelectric conversion portion PD disposed in the semiconductor substrate 101, a charge holding portion MEM disposed in the semiconductor substrate 101, a gate 130 of a transfer transistor TRX, TRY, or TRG arranged on a region of a bottom surface 101A of the semiconductor substrate 101, the region overlapping the charge holding portion MEM, a sidewall 131 formed around the gate 130, and an in-substrate-shielding portion 112 that is a light-shielding portion disposed in a boundary region of a sensor pixel 50 in the semiconductor substrate 101 to extend like a wall from a light-receiving surface 101B of the semiconductor substrate 101toward the bottom surface 101A side. The in-substrate-shielding portion 112 has a penetrating portion 112A that penetrates the semiconductor substrate 101 and is in contact with the sidewall 130 at the penetrating portion 112A.

### TECHNICAL FIELD

The present disclosure relates to an imaging element that captures images by photoelectric conversion, a method for manufacturing the imaging element, and an electronic device.

### BACKGROUND ART

Global shutter-type imaging elements that capture images of all pixels at the same timing are known. In this type of imaging element, each pixel is provided with a charge holding portion that accumulates charges generated by a photoelectric conversion portion. In such an imaging element, when light enters the charge holding portion, unnecessary charges are generated and optical noise is generated. On the other hand, a technique has been proposed in which light is inhibited from entering the charge holding portion by forming a light-shielding portion around the charge holding portion (for example, PTLs 1 and 2).

### CITATION LIST

### Patent Literature

[PTL 1] JP 2015-228510 A

[PTL 2] WO 2018/008614

### SUMMARY

### Technical Problem

An object of the present disclosure is to provide an imaging element in which generation of optical noise is suppressed.

### Solution to Problem

An imaging element according to an aspect of the present disclosure includes a semiconductor substrate; a photoelectric conversion portion disposed in the semiconductor substrate to generate charges according to an amount of received light through photoelectric conversion; a charge holding portion disposed in the semiconductor substrate to hold charges transferred from the photoelectric conversion portion; a gate of a transfer transistor disposed on a region of a bottom surface of the semiconductor substrate, the region overlapping the charge holding portion; a sidewall formed around the gate; and an in-substrate-shielding portion that is a light-shielding portion disposed in a boundary region of sensor pixels in the semiconductor substrate to extend from a light-receiving surface of the semiconductor substrate toward the bottom surface side. The in-substrate-shielding portion has a penetrating portion that penetrates the semiconductor substrate, and is in contact with the sidewall at the penetrating portion. A width of the sidewall may be wider than a width of an end on the bottom surface side of the penetrating portion.

The imaging element may further include a light-receiving-surface-shielding portion that is a light-shielding portion that covers the light-receiving surface of the semiconductor substrate, the light-receiving-surface-shielding portion may have an opening formed in a region overlapping the photoelectric conversion portion, and an end of the in-substrate-shielding portion on the light-receiving surface side may be spaced apart from the opening. A distance from the opening to the end of the light-receiving surface side of the in-substrate-shielding portion may be 50 nm or more.

The imaging element may be a global shutter-type back-illuminated image sensor.

A method for manufacturing an imaging element according to an aspect of the present disclosure includes a photoelectric conversion portion forming step of forming a photoelectric conversion portion disposed in a semiconductor substrate to generate charges according to an amount of received light through photoelectric conversion; a charge holding portion forming step of forming a charge holding portion disposed in the semiconductor substrate to hold charges transferred from the photoelectric conversion portion; a gate forming step of forming a gate of a transfer transistor disposed on a region of a bottom surface of the semiconductor substrate, the region overlapping the charge holding portion; a sidewall forming step of forming a sidewall around the gate; and an in-substrate-shielding portion forming step of forming an in-substrate-shielding portion that is a light-shielding portion disposed in a boundary region of sensor pixels in the semiconductor substrate to extend from a light-receiving surface of the semiconductor substrate toward the bottom surface side. The in-substrate-shielding portion has a penetrating portion that penetrates the semiconductor substrate, and is in contact with the sidewall at the penetrating portion. The in-substrate-shielding portion forming step may include a trench forming step of forming a trench by etching using the sidewall as an etching stopper.

The method for manufacturing the imaging element may further include a light-receiving-surface-shielding portion forming step of forming a light-receiving-surface-shielding portion that is a light-shielding portion that covers the light-receiving surface; and an opening forming step of forming an opening in a region of the light-receiving-surface-shielding portion, the region overlapping the photoelectric conversion portion, and in the opening forming step, the opening may be formed such that an end of the in-substrate-shielding portion on the light-receiving surface side is spaced apart from the opening.

An electronic device according to an aspect of the present disclosure is an electronic device equipped with an imaging element, the imaging element including: a semiconductor substrate; a photoelectric conversion portion disposed in the semiconductor substrate to generate charges according to an amount of received light through photoelectric conversion; a charge holding portion disposed in the semiconductor substrate to hold charges transferred from the photoelectric conversion portion; a gate of a transfer transistor disposed on a region of a bottom surface of the semiconductor substrate, the region overlapping the charge holding portion; a sidewall formed around the gate; and an in-substrate-shielding portion that is a light-shielding portion disposed in a boundary region of sensor pixels in the semiconductor substrate to extend from a light-receiving surface of the semiconductor substrate toward the bottom surface side. The in-substrate-shielding portion has a penetrating portion that penetrates the semiconductor substrate, and is in contact with the sidewall at the penetrating portion.

### BRIEF DESCRIPTION OF DRAWINGS

FIG. 1 is a block diagram showing a schematic configuration of an imaging element according to the present embodiment.

FIG. 2 is an equivalent circuit diagram of a sensor pixel.

FIG. 3 is a plane layout diagram of a portion of the pixel region in a pixel array unit.

FIG. 4 is a longitudinal cross-sectional view showing the cross-sectional structure of the imaging element according to the present embodiment, taken along the line A-A in FIG. 3.

FIG. 5 is a plane layout diagram showing the arrangement of first light-shielding portions.

FIG. 6 is a plane layout diagram showing the arrangement of second and third light-shielding portions.

FIG. 7 is a longitudinal cross-sectional view showing the details of the cross-sectional structure of the imaging element of the present embodiment.

FIG. 8 is an enlarged longitudinal cross-sectional view showing the cross-sectional structure of the imaging element of Comparative Example 1.

FIG. 9 is an enlarged longitudinal cross-sectional view showing the cross-sectional structure of an imaging element of Comparative Example 2.

FIG. 10 is a plane layout diagram showing that the opening can be made larger.

FIG. 11 is a plane layout diagram showing the arrangement of second and third light-shielding portions in the imaging element of Modified Example 1.

FIG. 12 is a longitudinal cross-sectional view showing a cross-sectional structure of an imaging element according to Modified Example 2.

FIG. 13A is a longitudinal cross-sectional view showing an example of the method for manufacturing the imaging element of the present embodiment, and shows the processing on the bottom side of the semiconductor substrate.

FIG. 13B is a longitudinal cross-sectional view subsequent to FIG. 13A.

FIG. 13C is a longitudinal cross-sectional view subsequent to FIG. 13B.

FIG. 13D is a longitudinal cross-sectional view subsequent to FIG. 13C.

FIG. 13E is a longitudinal cross-sectional view subsequent to FIG. 13D.

FIG. 14A is a longitudinal cross-sectional view showing an example of the method for manufacturing the imaging element of the present embodiment, showing the processing on the light-receiving surface side of the semiconductor substrate.

FIG. 14B is a longitudinal cross-sectional view subsequent to FIG. 14A.

FIG. 14C is a longitudinal cross-sectional view subsequent to FIG. 14B.

FIG. 14D is a longitudinal cross-sectional view subsequent to FIG. 14C.

FIG. 14E is a longitudinal cross-sectional view subsequent to FIG. 14D.

FIG. 14F is a longitudinal cross-sectional view subsequent to FIG. 14E.

FIG. 14G is a longitudinal cross-sectional view subsequent to FIG. 14F.

FIG. 14H is a longitudinal cross-sectional view subsequent to FIG. 14G.

FIG. 14I is a longitudinal cross-sectional view subsequent to FIG. 14H.

FIG. 14J is a longitudinal cross-sectional view subsequent to FIG. 14I.

FIG. 15 is a block diagram showing a configuration example of a camera as an electronic device.

FIG. 16 is a block diagram showing a schematic configuration example of a vehicle control system, which is an example of a mobile object control system.

FIG. 17 is a diagram showing an example of the installation position of the imaging unit.

FIG. 18 is a diagram showing one example of a schematic configuration of an endoscopic surgery system.

FIG. 19 is a block diagram showing an example of a functional configuration of a camera head and a CCU.

### DESCRIPTION OF EMBODIMENTS

Hereinafter, an example of an embodiment of the present disclosure (hereinafter referred to as “present embodiment”) will be explained with reference to the drawings. Note that the explanation will be given in the following order.
1. Structure of imaging element of present embodiment
2. Modified Example
3. Method for manufacturing imaging element of present embodiment
4. Example of application to electronic device
5. Example of application to mobile object
6. Application example to endoscopic surgery system
7. Summary
1. Structure of Imaging Element of Present Embodiment

An imaging element 10 of the present embodiment is a global shutter-type back-illuminated image sensor using a complementary metal oxide semiconductor (CMOS) image sensor. The imaging element 10 of the present embodiment receives light from a subject for each pixel, performs photoelectric conversion, and generates a pixel signal that is an electrical signal.

The global shutter method is a method in which exposure of all pixels starts and ends at the same time. Here, all pixels refer to all pixels that form a valid image, and dummy pixels and the like that do not contribute to image formation are excluded. Furthermore, they do not necessarily have to be done at the same time if the image distortion and exposure time difference are small enough to not be a problem, For example, the global shutter method also includes the case where the operation of performing simultaneous exposure in units of multiple rows (such as several tens of rows) is repeated while shifting in units of multiple rows in the row direction. In addition, a case where simultaneous exposure is performed only on a portion of the pixel region is also included in the global shutter system.

A back-illuminated image sensor is a type of image sensor in which a photoelectric conversion portion such as a photodiode that receives light from a subject and converts it into an electrical signal is arranged for each pixel between a light-receiving surface where light from the subject enters and a wiring layer that has wiring such as transistors that drive each pixel. Note that the technology according to the present disclosure may be applicable to image sensors using imaging methods other than CMOS image sensors.

### (Block Configuration of Imaging Element 10)

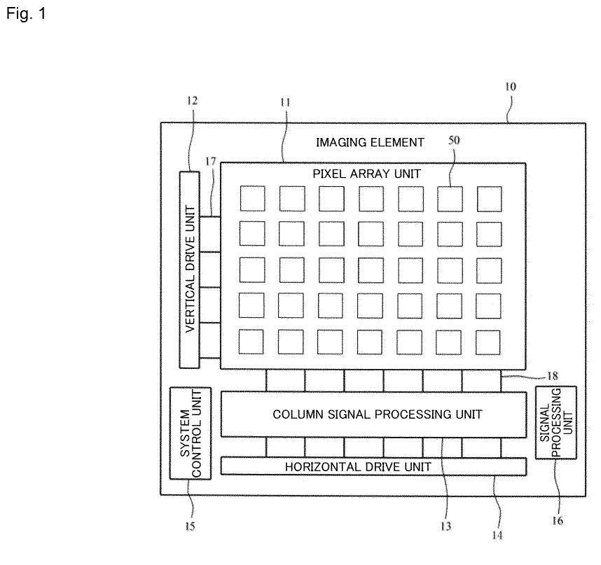

FIG. 1 is a block diagram showing a schematic configuration of an imaging element 10 of the present embodiment.

As described later, the imaging element 10 of the present embodiment is formed on the semiconductor substrate 101, so it is technically a solid-state imaging element, but hereinafter it will simply be referred to as an imaging element.

The imaging element 10 includes, for example, a pixel array unit 11, a vertical drive unit 12, a column signal processing unit 13, a horizontal drive unit 14, a system control unit 15, and a signal processing unit 16.

The pixel array unit 11 has a plurality of sensor pixels 50 including photoelectric conversion portions PD that generate and accumulate charges according to the amount of light incident from the subject. As shown in FIG. 1, the plurality of sensor pixels 50 are arranged in the horizontal direction (row direction) and the vertical direction (column direction). The sensor pixel 50 corresponds to a pixel of the imaging element 10.

Further, the pixel array unit 11 includes a pixel drive line 17 and a vertical signal line 18. The pixel drive line 17 is wired along the row direction for each pixel row made up of sensor pixels 50 arranged in a line in the row direction. The vertical signal line 18 is wired along the column direction for each pixel column made up of sensor pixels 50 arranged in a line in the column direction.

The vertical drive unit 12 is configured with a shift register or an address decoder. The vertical drive unit 12 drives all of the plurality of sensor pixels 50 in the pixel array unit 11 simultaneously or in units of pixel rows by supplying signals and the like to the plurality of sensor pixels 50 via the plurality of pixel drive lines 17.

The column signal processing unit 13 is configured with a shift register or an address decoder, and performs noise removal processing, correlated double sampling processing, A/D conversion processing, and the like to generate pixel signals. The column signal processing unit 13 supplies the generated pixel signals to the signal processing unit 16.

The horizontal drive unit 14 selects unit circuits of the column signal processing unit 13 corresponding to the pixel columns in order. Due to this selective scanning by the horizontal drive unit 14, pixel signals subjected to signal processing for each unit circuit in the column signal processing unit 13 are sequentially output to the signal processing unit 16.

The system control unit 15 is configured with a timing generator or the like that generates various timing signals. The system control unit 15 controls the vertical drive unit 12, the column signal processing unit 13, and the horizontal drive unit 14 based on the timing signal generated by the timing generator.

The signal processing unit 16 performs signal processing such as arithmetic processing on the pixel signals supplied from the column signal processing unit 13 as necessary, and outputs an image signal made up of each pixel signal.

### (Circuit Configuration of Sensor Pixel 50)

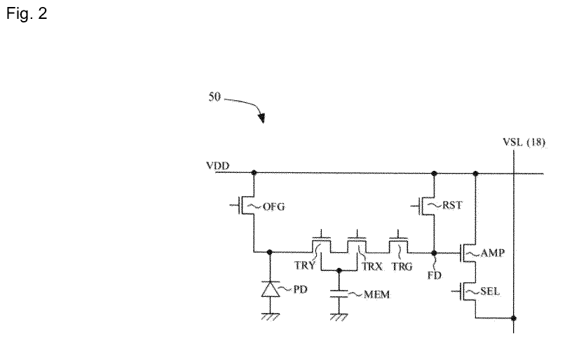

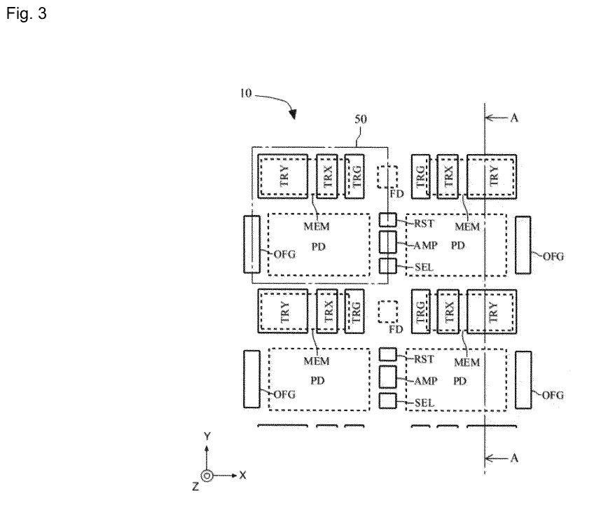

FIG. 2 is an equivalent circuit diagram of the sensor pixel 50. FIG. 3 is a plane layout diagram of a portion of a pixel region in the pixel array unit 11. FIG. 3 shows a pixel region for four pixels.

As shown in FIGS. 2 and 3, the sensor pixel 50 includes a photoelectric conversion portion PD, a charge holding portion MEM, three transfer transistors TRY, TRX, and TRG, a floating diffusion region FD, a discharge transistor OFG, a reset transistor RST, an amplification transistor AMP, and a selection transistor SEL.

The photoelectric conversion portion PD is configured as, for example, a photodiode, and generates charges according to the amount of received light by photoelectric conversion.

The charge holding portion MEM is a region that temporarily holds charges generated and accumulated in the photoelectric conversion portion PD in order to realize a global shutter function. The charge holding portion MEM holds charges transferred from the photoelectric conversion portion PD.

The transfer transistors TRY and TRX are arranged on the charge holding portion MEM in the order of the transfer transistors TRY and TRX from the photoelectric conversion portion PD side. The gates of the transfer transistors TRY and TRX are connected to the pixel drive line 17. The transfer transistors TRY and TRX control the potential of the charge holding portion MEM by a control signal applied to the gate electrode, and transfer the charges photoelectrically converted by the photoelectric conversion portion PD.

For example, the potential of the charge holding portion MEM becomes deep when the transfer transistors TRY and TRX are turned on, and the potential of the charge holding portion MEM becomes shallow when the transfer transistors TRY and TRX are turned off. Then, for example, when the transfer transistors TRY and TRX are turned on, the charges accumulated in the photoelectric conversion portion PD are transferred to the charge holding portion MEM via the transfer transistors TRY and TRX.

The transfer transistor TRG is arranged between the transfer transistor TRX and the floating diffusion region FD. The source of the transfer transistor TRG is electrically connected to the drain of the transfer transistor TRX, and the drain of the transfer transistor TRG is electrically connected to the floating diffusion region FD. The gate of the transfer transistor TRG is connected to the pixel drive line 17.

The transfer transistor TRG transfers the charges held in the charge holding portion MEM to the floating diffusion region FD in accordance with a control signal applied to the gate electrode.

For example, when the transfer transistor TRX is turned off and the transfer transistor TRG is turned on, the charges held in the charge holding portion MEM are transferred to the floating diffusion region FD.

The floating diffusion region FD is a region that temporarily holds charges output from the photoelectric conversion portion PD via the transfer transistor TRG. For example, the reset transistor RST is connected to the floating diffusion region FD, and the vertical signal line 18 (VSL) is also connected to the floating diffusion region FD via the amplification transistor AMP and the selection transistor SEL.

The amplification transistor AMP has a gate electrode connected to the floating diffusion region FD, a drain connected to the power supply line VDD, and serves as an input portion of a source follower circuit that reads out the charge obtained by photoelectric conversion in the photoelectric conversion portion PD. That is, the amplification transistor AMP has a source connected to the vertical signal line 18 (VSL) via the selection transistor SEL, so that the amplification transistor AMP forms a source follower circuit together with a constant current source (not shown) connected to one end of the vertical signal line 18 (VSL).

The selection transistor SEL is connected between the source of the amplification transistor AMP and the vertical signal line 18 (VSL). A control signal as a selection signal is supplied to the gate electrode of the selection transistor SEL. The selection transistor SEL becomes conductive when the control signal is turned on, and the sensor pixel 50 connected to the selection transistor SEL becomes selected. When the sensor pixel 50 is in the selected state, the pixel signal output from the amplification transistor AMP is read out to the column signal processing unit 13 via the vertical signal line 18 (VSL).

The discharge transistor OFG initializes (resets) the photoelectric conversion portion PD according to a control signal applied to the gate electrode. The drain of the discharge transistor OFG is connected to the power supply line VDD. The source of the discharge transistor OFG is connected between the photoelectric conversion portion PD and the transfer transistor TRY.

For example, when the discharge transistor OFG is turned on, the potential of the photoelectric conversion portion PD is reset to the potential level of the power supply line VDD. That is, the photoelectric conversion portion PD is initialized. Further, the discharge transistor OFG forms an overflow path between the photoelectric conversion portion PD and the power supply line VDD, for example, and discharges the charge overflowing from the photoelectric conversion portion PD to the power supply line VDD.

The reset transistor RST initializes (resets) each region from the charge holding portion MEM to the floating diffusion region FD according to a control signal applied to the gate electrode. The drain of the reset transistor RST is connected to the power supply line VDD. The source of the reset transistor RST is connected to the floating diffusion region FD.

For example, when the transfer transistor TRG and the reset transistor RST are turned on, the potentials of the charge holding portion MEM and the floating diffusion region FD are reset to the potential level of the power supply line VDD. That is, by turning on the reset transistor RST, the charge holding portion MEM and the floating diffusion region FD are initialized.

Note that the plane layout of each transistor in the sensor pixel 50 is not limited to that shown in FIG. 3. If the arrangement of transistors in the sensor pixel 50 changes, the arrangement locations of the photoelectric conversion portion PD and the charge holding portion MEM arranged below the transistors also change.

### (Summary of Structure of Imaging Element 10)

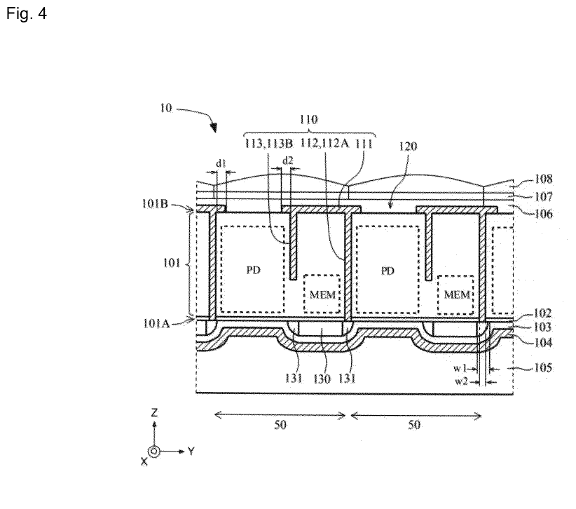

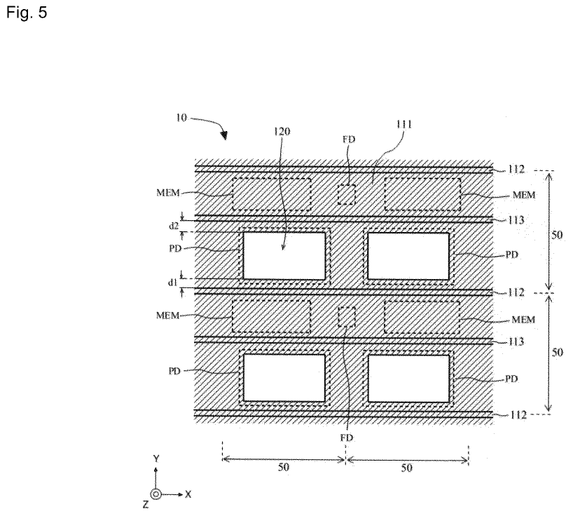

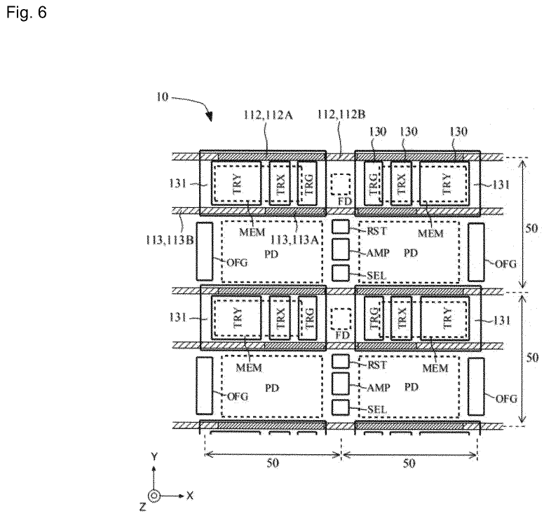

FIG. 4 is a longitudinal cross-sectional view showing the cross-sectional structure of the imaging element 10 of the present embodiment, taken along the line A-A in FIG. 3. FIGS. 5 and 6 are plane layout diagrams showing the arrangement of the light-shielding portion 110. FIG. 5 shows the arrangement of the first light-shielding portion 111, and FIG. 6 shows the arrangement of the second and third light-shielding portions 112 and 113.

The imaging element 10 includes a semiconductor substrate 101, insulating layers 102 and 103, a light-shielding layer 104, and a wiring layer 105, which are stacked in order from the top in the drawing. The imaging element 10 also includes a photoelectric conversion portion PD and a charge holding portion MEM formed in the semiconductor substrate 101, and a gate 130 formed between the insulating layer 102 and the insulating layer 103. A sidewall 131 is formed around this gate 130. Further, the imaging element 10 has a light-shielding portion 110 formed on and inside the light-receiving surface 101B of the semiconductor substrate 101.

In this specification, one main surface of the semiconductor substrate 101 on the side where the wiring layer 105 is arranged (lower side in FIG. 4) is referred to as a bottom surface 101A, and one main surface on the opposite side (upper side in FIG. 4) is referred to as a light-receiving surface 101B. The bottom surface 101A is a surface opposite to the light incident surface of the semiconductor substrate 101. The light-receiving surface 101B is a light incident surface of the semiconductor substrate 101. Further, in this specification, the bottom surface 101A may be referred to as the front surface or the first surface, and the light-receiving surface 101B may be referred to as the back surface or the second surface.

The semiconductor substrate 101 is made of, for example, a silicon substrate.

The insulating layers 102 and 103 are layers having insulating properties. The insulating layers 102 and 103 insulate the semiconductor substrate 101 and the wiring layer 105. The insulating layer 102 also serves as an insulating film between the gate 130 and the semiconductor substrate 101.

The light-shielding layer 104 is a layer having light-shielding properties and has excellent light absorption or reflection properties. The light shielding layer 104 prevents light that has passed through the semiconductor substrate 101 without being absorbed by the photoelectric conversion portion PD from entering the wiring layer 105. In this way, light that has passed through the semiconductor substrate 101 is suppressed from entering the wiring layer 105, being reflected by the wiring layer 105, and entering the charge holding portion MEM.

The gate 130 corresponds to the gate of the transfer transistor TRY. The sidewall 131 of the gate 130 is made of an insulating material and a material that functions as an etching stopper. Further, the width W1 of the sidewall 131 is set wider than the width W2 at the end of the bottom surface 101A side of the penetrating portions 112A and 113A of the second and third light-shielding portions 112 and 113, which will be described later. The gate 130 shown in FIG. 4 corresponds to the gate of the transfer transistor TRY, but the gates 130 of the transfer transistors TRX and TRG also have a similar structure.

The light-shielding portion 110 is a member having a light-shielding property and has excellent light absorption or reflection properties. The light-shielding portion 110 includes a first light-shielding portion 111 formed on the light-receiving surface 101B of the semiconductor substrate 101, and second and third light-shielding portions 112 and 113 shaped like a wall connected to the first light-shielding portion 111 and extending from the light-receiving surface 101B of the semiconductor substrate 101 toward the bottom surface 101A. Note that in this specification, the first light-shielding portion 111 may be referred to as a “light-receiving-surface-shielding portion”, and the second and third light-shielding portions 112 and 113 may be referred to as “in-substrate-shielding portions”.

As shown in FIGS. 4 and 5, the first light-shielding portion 111 is formed to cover the region of the light-receiving surface 101B except for the region above the photoelectric conversion portion PD. That is, the first light-shielding portion 111 has an opening 120 formed in a region overlapping the photoelectric conversion portion PD. The first light-shielding portion 111 suppresses light from entering a region other than the photoelectric conversion portion PD.

As shown in FIGS. 4 and 6, the second light-shielding portion 112 is located in the boundary region of the sensor pixel 50 and is formed to extend from the light-receiving surface 101B toward the bottom surface 101A and spread in the in-plane direction of a plane perpendicular to the light-receiving surface 101B. In the illustrated example, the second light-shielding portion 112 extends in the in-plane direction of the XZ plane. Further, the second light-shielding portion 112 extends across the plurality of sensor pixels 50 in the X-axis direction. The second light-shielding portion 112 suppresses incident light that has not been absorbed by the photoelectric conversion portion PD from entering the charge holding portion MEM of the adjacent sensor pixel 50.

The second light-shielding portion 112 has a penetrating portion 112A that penetrates the semiconductor substrate 101 and a non-penetrating portion 112B that does not penetrate the semiconductor substrate 101. The penetrating portion 112A penetrates the semiconductor substrate 101 and is in contact with the sidewall 131 of the gate 130. On the other hand, the non-penetrating portion 112B does not penetrate the semiconductor substrate 101, and its end on the bottom surface 101A side exists inside the semiconductor substrate 101. In the illustrated example, the penetrating portion 112A is arranged in a region around the photoelectric conversion portion PD, and the non-penetrating portion 112B is arranged in another region.

The fact that the penetrating portion 112A of the second light-shielding portion 112 is in contact with the sidewall 131 of the gate 130 in this manner is one of the technical features of the imaging element 10 of the present embodiment. Details of this point will be described later.

As shown in FIGS. 4 and 6, the third light-shielding portion 113 is located in an intermediate region between the photoelectric conversion portion PD and the charge holding portion MEM in the sensor pixel 50, and is formed to extend from the light-receiving surface 101B toward the bottom surface 101A and spread in the in-plane direction of a plane perpendicular to the light-receiving surface 101B. In the illustrated example, the third light-shielding portion 113 extends in the in-plane direction of the XZ plane. Furthermore, the third light-shielding portion 113 extends across the plurality of sensor pixels 50 in the X-axis direction. The third light-shielding portion 113 suppresses incident light that has not been absorbed by the photoelectric conversion portion PD from entering the charge holding portion MEM in the sensor pixel 50.

Like the second light-shielding portion 112, the third light-shielding portion 113 has a penetrating portion 113A that penetrates the semiconductor substrate 101 and a non-penetrating portion 113B that does not penetrate the semiconductor substrate 101. The penetrating portion 113A penetrates the semiconductor substrate 101 and is connected to the sidewall 131 of the gate 130. On the other hand, the non-penetrating portion 113B does not penetrate the semiconductor substrate 101, and its end on the bottom surface 101A side exists inside the semiconductor substrate 101. In the illustrated example, the penetrating portion 113A is arranged in a region between the photoelectric conversion portion PD and the transfer transistors TRX, TRG, and the non-penetrating portion 113B is arranged in another region.

Furthermore, in the imaging element 10 of the present embodiment, the ends of the second and third light-shielding portions 112 and 113 on the light-receiving surface 101B side are spaced apart from the opening 120 of the first light-shielding portion 111. Furthermore, in the imaging element 10 of the present embodiment, the distance d1 from the opening 120 of the first light-shielding portion 111 to the end of the second light-shielding portion 112 on the light-receiving surface 101B side is 50 nm or more. Further, in the imaging element 10 of the present embodiment, the distance d2 from the opening 120 of the first light-shielding portion 111 to the end of the third light-shielding portion 113 on the light-receiving surface 101B side is 50 nm or more.

With this configuration, in the imaging element 10 of the present embodiment, etching damage occurring in the peripheral regions of the sidewalls of the second and third light-shielding portions 112 and 113 during manufacturing is reduced, and the occurrence of white spots is suppressed. Details of this point will be described later.

Note that, as shown in FIG. 4, on the light-receiving surface 101B of the semiconductor substrate 101, for example, an insulating layer 106, a color filter 107, a microlens 108, and the like are stacked. Further, although not shown, a support substrate, for example, is stacked on the bottom surface of the wiring layer 105. In the following drawings, illustrations of the support substrate, insulating layer 106, color filter 107, microlens 108, and the like are omitted.

### (Details of Structure of Imaging Element 10)

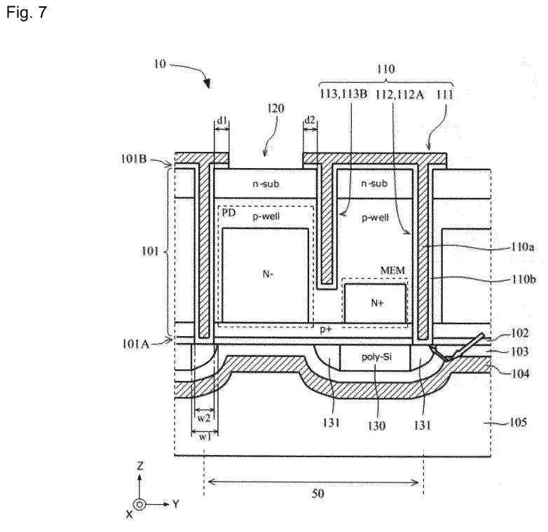

FIG. 7 is a longitudinal cross-sectional view showing the details of the cross-sectional structure of the imaging element 10 of the present embodiment.

In the imaging element 10 of the present embodiment, an N-type silicon substrate is used as the semiconductor substrate 101. In the figure, “n-sub” indicates an N-type substrate region, and “p-well” indicates a P-type well region. Further, symbols “P” and “N” in the figure represent a P-type semiconductor region and an N-type semiconductor region, respectively. Furthermore, the suffix “+” or “−” in each of the symbols “P+”, “N−”, and “N+” represents the impurity concentration. “+” indicates that the impurity concentration is high, and “−” indicates that the impurity concentration is low. The same applies to subsequent figures.

In the example shown in FIG. 7, a P-type well (p-well) is formed in an N-type semiconductor substrate 101, and a photoelectric conversion portion PD and a charge holding portion MEM are formed within the P-type well.

The photoelectric conversion portion PD has a P-type semiconductor region (p-well) and an N−-type semiconductor region in order from a position close to the light-receiving surface 101B. Light incident from the light-receiving surface 101B is photoelectrically converted in the N−-type semiconductor region to generate charges. The charges generated therein are accumulated in the N−-type semiconductor region. Further, a P+-type semiconductor region is formed between the N−-type semiconductor region and the bottom surface 101A of the semiconductor substrate 101. This P+-type semiconductor region is a region for pinning the surface level of the semiconductor substrate 101. Note that the layer structure of the photoelectric conversion portion PD formed in the semiconductor substrate 101 is not necessarily limited to that shown in FIG. 7.

The charge holding portion MEM is configured as an N+-type semiconductor region provided within a P-type semiconductor region (p-well). Further, a P+-type semiconductor region is formed between the N+-type semiconductor region and the bottom surface 101A of the semiconductor substrate 101. This P+-type semiconductor region is a region for pinning the surface level of the semiconductor substrate 101.

The insulating layers 102 and 103 are made of, for example, SiO₂ (silicon oxide), SiN (silicon nitride), or the like. The insulating layer 102 also serves as an insulating film for a gate 130, which will be described later. The insulating layer 103 may include a plurality of layers each made of a different insulating material. In addition, part or all of the insulating layer 102 may be formed integrally with the insulating layer 102.

The light-shielding layer 104 is made of, for example, metals such as tungsten (W), aluminum (Al), copper (Cu), silver (Ag), Au (gold), platinum (Pt), molybdenum (Mo), chromium (Cr), titanium (Ti), nickel (Ni), or iron (Fe), semiconductors such as silicon (Si), germanium (Ge), or tellurium (Te), and alloys thereof. Further, the light-shielding layer 104 can also have a stacked structure of these metals.

The gate 130 of the transfer transistor TRY is provided on the bottom surface 101A side of the semiconductor substrate 101 with an insulating layer 102 interposed therebetween. Further, the gate 130 is arranged in a region that at least partially overlaps the charge holding portion MEM. The gate 130 is made of, for example, P-type polysilicon.

The sidewall 131 formed around the gate 130 is made of an insulating material, such as SiN (silicon nitride), and a material that functions as an etching stopper. The gates of the transfer transistors TRX and TRG also have the same configuration as the gate 130 of the transfer transistor TRY.

Although not shown, the floating diffusion region FD is configured as an N+-type semiconductor region provided within a P-type semiconductor region (p-well).

The light-shielding portion 110 includes a light-shielding material portion 110a and an insulating film 110b covering the periphery thereof. Furthermore, the light-shielding portion 110 may have a fixed charge layer formed around the insulating film 110b. The fixed charge layer can be formed, for example, as a P+-type semiconductor region.

The light-shielding material portion 110a is made of metal such as tungsten (W), aluminum (Al), or copper (Cu), for example.

The insulating film 110b is made of an insulating material such as SiO₂ (silicon oxide), for example. The insulating film 110b ensures electrical insulation between the light-shielding material portion 110a and the semiconductor substrate 101.

As shown in FIG. 7, in the imaging element 10 of the present embodiment, the penetrating portion 112A of the second light-shielding portion 112 is in contact with the sidewall 131 of the gate 130. More specifically, in the imaging element 10 of the present embodiment, the end of the penetrating portion 112A of the second light-shielding portion 112 on the bottom surface 101A side is in contact with the sidewall 131 of the gate 130.

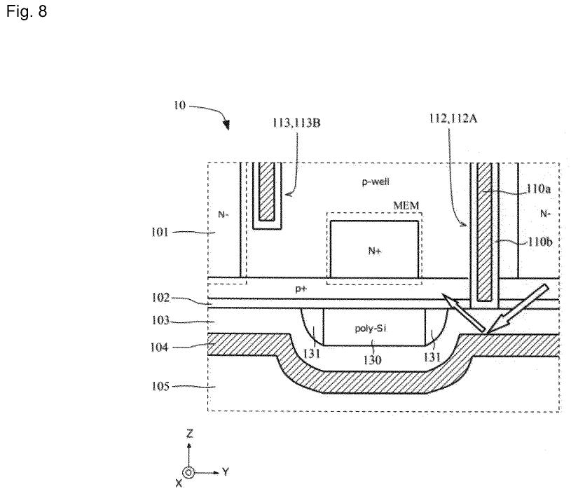

FIG. 8 is an enlarged longitudinal cross-sectional view showing the cross-sectional structure of the imaging element 10 of Comparative Example 1. In the imaging element 10 of Comparative Example 1, the bottom of the penetrating portion 112A of the second light-shielding portion 112 is located away from the sidewall 131 of the gate 130.

In the imaging element 10 of Comparative Example 1, as shown in FIG. 8, the light having passed through the semiconductor substrate 101 and reached between the penetrating portion 112A of the second light-shielding portion 112 and the light-shielding layer 104 without being absorbed by the photoelectric conversion portion PD passes through only the insulating layer 103 and reaches the charge holding portion MEM of the adjacent sensor pixel 50.

On the other hand, in the imaging element 10 of the present embodiment, as shown in FIG. 7, the light having passed through the semiconductor substrate 101 and reached between the penetrating portion 112A of the second light-shielding portion 112 and the light-shielding layer 104 without being absorbed by the photoelectric conversion portion PD passes through the three layers of the insulating layer 103, the sidewall 131, and the insulating film 110b and reaches the charge holding portion MEM of the adjacent sensor pixel 50. As the number of layers through which light passes increases, the number of interfaces through which light passes increases accordingly. Since light is reflected and scattered at the interface, the more the number of layers through which the light passes, the more the incidence of the light on the charge holding portion MEM is suppressed.

Therefore, the imaging element 10 of the present embodiment is more effective than the imaging element 10 of Comparative Example 1 in that light having passed through the semiconductor substrate 101 without being absorbed by the photoelectric conversion portion PD is suppressed from entering the charge holding portion MEM of the adjacent sensor pixel 50. In short, in the imaging element 10 of the present embodiment, the occurrence of crosstalk between adjacent sensor pixels 50 is suppressed.

Furthermore, as described above, since the more the number of layers through which the light passes before reaching the charge holding portion MEM, the more the incidence of light on the charge holding portion MEM is suppressed, it is preferable that the insulating layer 103 has multiple layers each made of a different insulating material.

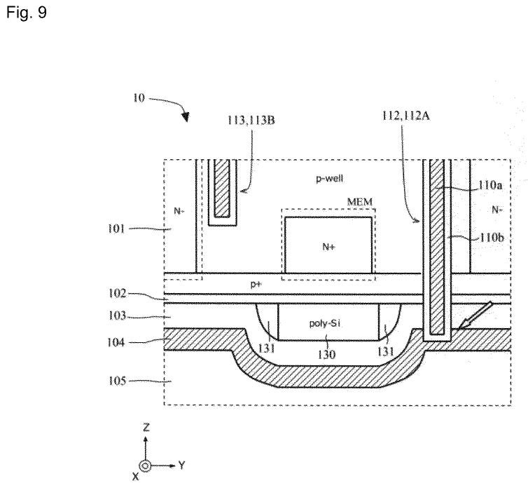

FIG. 9 is an enlarged longitudinal cross-sectional view showing the cross-sectional structure of the imaging element 10 of Comparative Example 2. In the imaging element 10 of Comparative Example 2, the penetrating portion 112A of the second light-shielding portion 112 also penetrates the insulating layer 103 and is in contact with the light-shielding layer 104.

In the imaging element 10 of Comparative Example 2, the penetrating portion 112A of the second light-shielding portion 112 and the light-shielding layer 104 are in contact with each other, so that the occurrence of crosstalk is suppressed. However, in this configuration, the disclosers of the present disclosure have found that the dark characteristics of the imaging element 10 may deteriorate due to damage to the semiconductor substrate 101 and the like due to etching during trench processing for forming the penetrating portion 112A, and contamination due to exposure of the light-shielding material of the light-shielding layer 104.

On the other hand, in the imaging element 10 of the present embodiment, the occurrence of crosstalk between adjacent sensor pixels 50 is suppressed without causing such deterioration of the dark characteristics.

In the above, the penetrating portion 112A of the second light-shielding portion 112 arranged in the boundary region of the sensor pixel 50 has been described, but the same explanation applies to the penetrating portion 113A of the third light-shielding portion 113 arranged in the intermediate region between the photoelectric conversion portion PD in the sensor pixel 50 and the charge holding portion MEM.

That is, in the imaging element 10 of the present embodiment, the penetrating portion 113A of the third light-shielding portion 113 is also in contact with the sidewall 131 of the gate 130 (see FIG. 6). Therefore, in the imaging element 10 of the present embodiment, light having passed through the semiconductor substrate 101 without being absorbed by the photoelectric conversion portion PD is suppressed from entering the charge holding portion MEM in the sensor pixel 50. In short, in the imaging element 10 of the present embodiment, the occurrence of crosstalk within the sensor pixel 50 is suppressed. Further, in the imaging element 10 of the present embodiment, the occurrence of crosstalk within the sensor pixel 50 is suppressed without causing such deterioration of the dark characteristics.

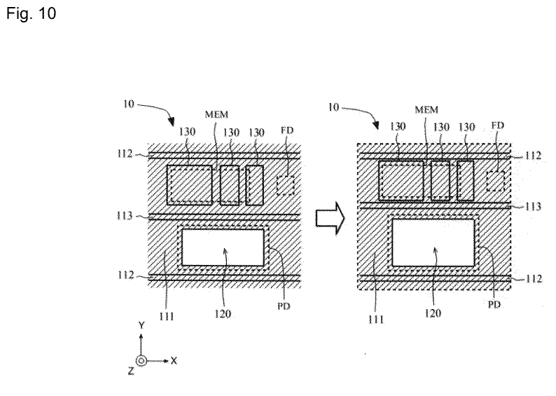

Furthermore, in the imaging element 10 of the present embodiment, as shown in FIGS. 6 and 10, since the second and third light-shielding portions 112 and 113 are arranged close to the gate 130, it is possible to miniaturize the sensor pixel 50 and enlarge the photoelectric conversion portion PD and the opening 120. FIG. 10 is a plane layout diagram showing that the opening 120 can be enlarged, in which the left figure shows the conventional imaging element 10, and the right figure shows the imaging element 10 of the present embodiment.

By enlarging the photoelectric conversion portion PD, it is possible to improve the sensitivity and Qs (saturated charge amount) of the imaging element 10. Furthermore, by enlarging the opening 120, it is possible to improve the sensitivity and oblique incidence characteristics of the imaging element 10.

In other words, the imaging element 10 of the present embodiment can simultaneously suppress the occurrence of crosstalk, miniaturize the sensor pixels 50, and improve the sensitivity, Qs (saturated charge amount), and oblique incidence characteristics of the imaging element 10.

Furthermore, as a result of research, the disclosers of the present disclosure have found that the occurrence of white spots on the imaging element 10 can be suppressed by increasing the distance d1 from the opening 120 of the first light-shielding portion 111 to the end of the second light-shielding portion 112 on the light receiving surface 101B side and the distance d2 from the opening 120 of the first light-shielding portion 111 to the end of the third light-shielding portion 113 on the light-receiving surface 101B side.

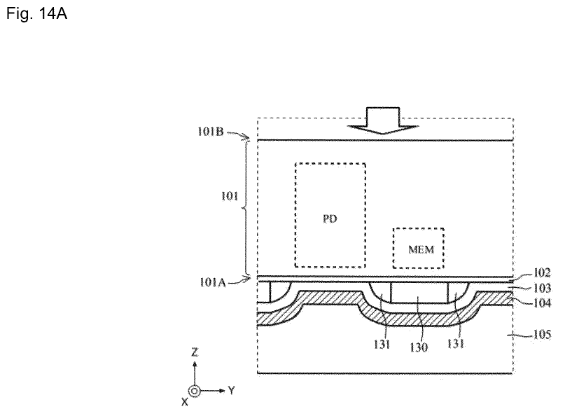

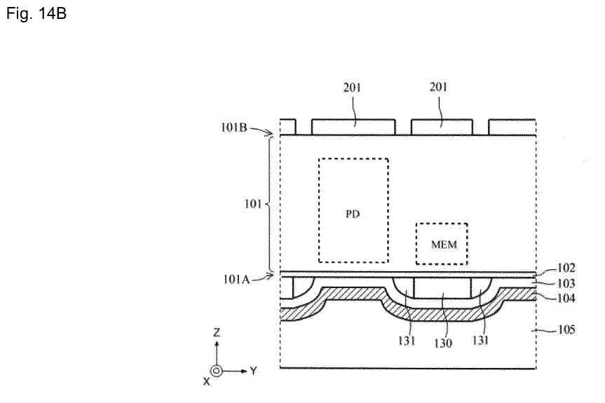

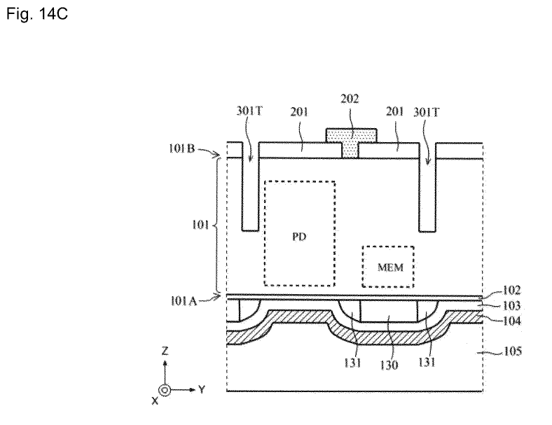

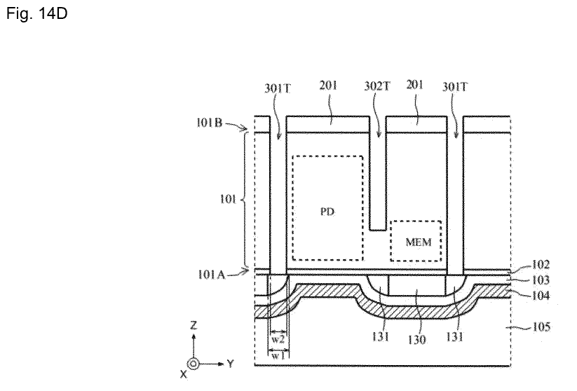

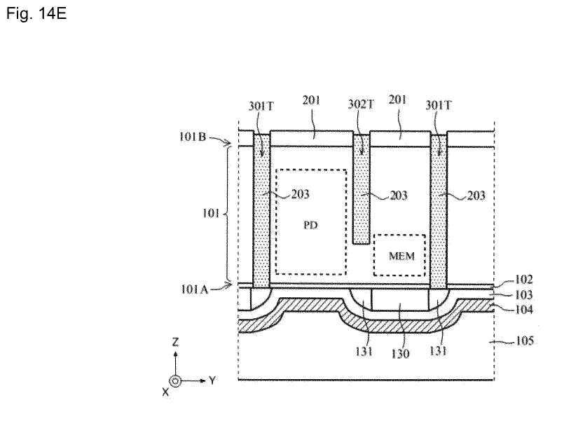

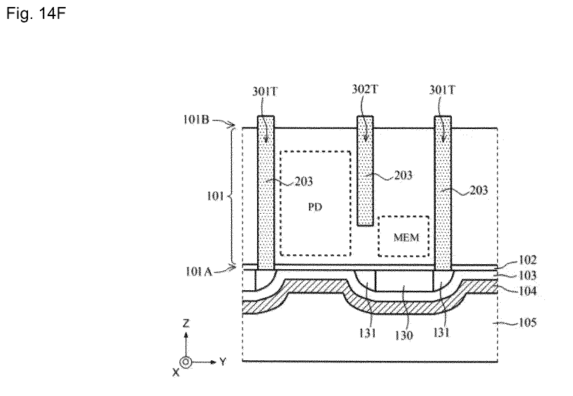

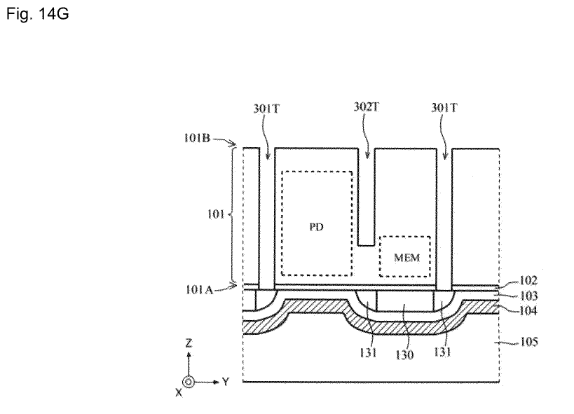

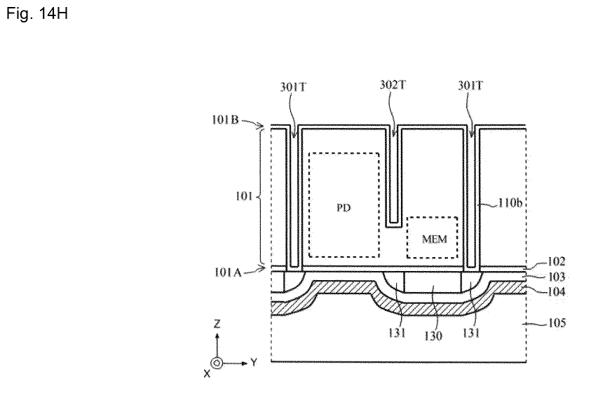

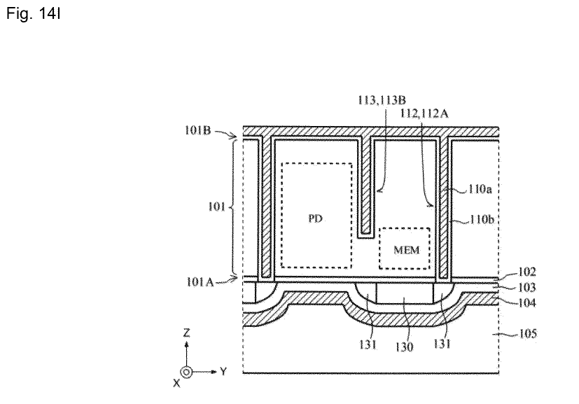

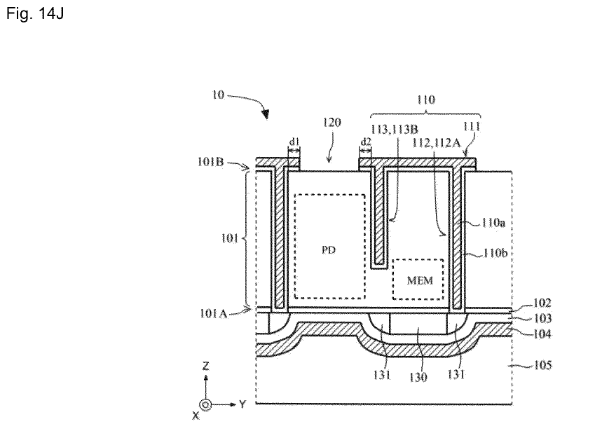

In addition, the disclosers of the present disclosure have found that the occurrence of white spots is suppressed because etching damage occurring in the peripheral regions of the sidewalls of the second and third light-shielding portions 112 and 113 when forming the opening 120 during manufacturing of the imaging element 10 (see FIG. 14J) is reduced when the distances d1 and d2 are increased. Specifically, the peripheral regions of the sidewall portions of the second and third light-shielding portions 112 and 113 are the boundary region between the second or third light-shielding portions 112 and 113 and the semiconductor substrate 101.

Furthermore, the disclosers of the present disclosure have found that the occurrence of white spots can be effectively suppressed by setting the distances d1 and d2 to 50 nm or more.

Therefore, one of the features of the imaging element 10 of the present embodiment is that the ends of the second and third light-shielding portions 112 and 113 on the light-receiving surface 101B side are spaced apart from the opening 120 of the first light-shielding portion 111. Furthermore, another feature of the imaging element 10 of the present embodiment is that the distance d1 from the opening 120 of the first light-shielding portion 111 to the end of the second light-shielding portion 112 on the light-receiving surface 101B side is 50 nm or more. Another feature is that the distance d2 from the opening 120 of the first light-shielding portion 111 to the end of the third light-shielding portion 113 on the light-receiving surface 101B side is 50 nm or more.

Here, the positions of the ends of the second and third light-shielding portions 112 and 113 on the light-receiving surface 101B side refer to the position of the processing interface of the semiconductor substrate 101, more specifically, the positions of the opening edges on the light-receiving surface 101B side, of the trenches 301T and 302T (see FIG. 14G) formed during manufacturing, which will be described later. In the example shown in FIG. 7, the positions of the ends of the second and third light-shielding portions 112 and 113 on the light-receiving surface 101B side are the ends on the light-receiving surface 101B side, of the interface between the insulating film 110b and the semiconductor substrate 101.

As described above, in the imaging element 10 of the present embodiment, by setting the above-mentioned distances d1 and d2 to 50 nm or more, etching damage that occurs in the peripheral regions of the sidewalls of the second and third light-shielding portions 112 and 113 during manufacturing is reduced and the occurrence of white spots is suppressed.

However, in the imaging element 10 of the present disclosure, one or both of the above-mentioned distances d1 and d2 may be less than 50 nm. If the advantages obtained by making the opening 120 larger outweigh the disadvantages caused by making the distances d1 and d2 smaller, it is possible to make the distances d1 and d2 less than 50 nm.

To summarize the above, the imaging element 10 of the present embodiment includes the semiconductor substrate 101, the photoelectric conversion portion PD, the charge holding portion MEM, the gates 130 of the transfer transistors TRX, TRY, and TRG arranged on a region of the bottom surface 101A of the semiconductor substrate 101, the region overlapping the charge holding portion MEM, the sidewall 131 formed around the gates 130, and the second light-shielding portion (in-substrate-shielding portion) 112 arranged in the boundary region of the sensor pixel 50 in the semiconductor substrate 101. The second light-shielding portion (in-substrate-shielding portion) 112 has the penetrating portion 112A that penetrates the semiconductor substrate 101, and is in contact with the sidewall 130 at the penetrating portion 112A.

In such an imaging element 10, since the occurrence of crosstalk between the sensor pixels 50 and within the sensor pixel 50 is suppressed, the generation of optical noise is suppressed.

Furthermore, the imaging element 10 of the present embodiment further includes the first light-shielding portion (light-receiving-surface-shielding portion) 111 that covers the light-receiving surface 101B of the semiconductor substrate 101, the first light-shielding portion (light-receiving-surface-shielding portion) 111 includes the opening 120 formed in a region overlapping the photoelectric conversion portion MEM, and the end of the second light-shielding portion (in-substrate-shielding portion) 112 on the light-receiving surface 101B side is spaced apart from the opening 120.

Since such an imaging element 10 has reduced etching damage during manufacturing, the occurrence of white spots is suppressed.

### 2. Modified Example

Next, a modified example of the imaging element 10 will be described.

### (Modified Example 1)

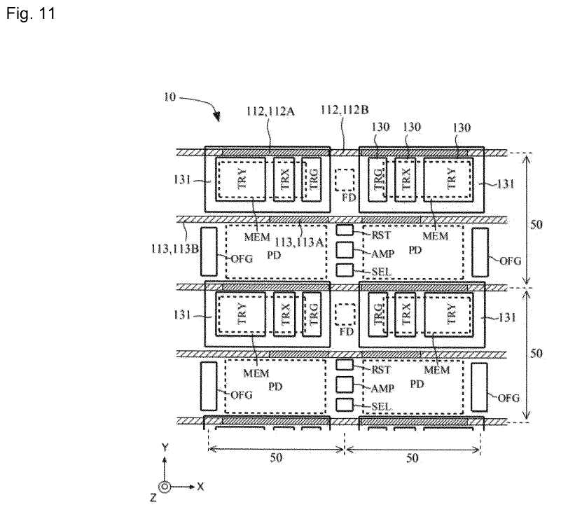

FIG. 11 is a plane layout diagram showing the arrangement of the second and third light-shielding portions 112 and 113 in the imaging element 10 of Modified Example 1.

In the imaging element 10 of Modified Example 1, the penetrating portion 113A of the third light-shielding portion 113 is located away from the sidewall 131. In this manner, in the imaging element 10 of the present disclosure, the penetrating portion 113A of the third light-shielding portion 113 may be located at a location away from the sidewall 131. In this case, there are fewer changes from the conventional imaging element 10. Therefore, the imaging element 10 of Modified Example 1 has the advantage that much of the design of the conventional imaging element 10 can be used. However, as in the imaging element 10 of the present embodiment, by making the penetrating portion 113A of the third light-shielding portion 113 also be in contact with the sidewall 131, crosstalk within the sensor pixel 50 can be further suppressed, and the miniaturization of the sensor pixel 50 and the sensitivity, Qs (saturated charge amount), and oblique incidence characteristics of the imaging element 10 can be further improved.

### (Modified Example 2)

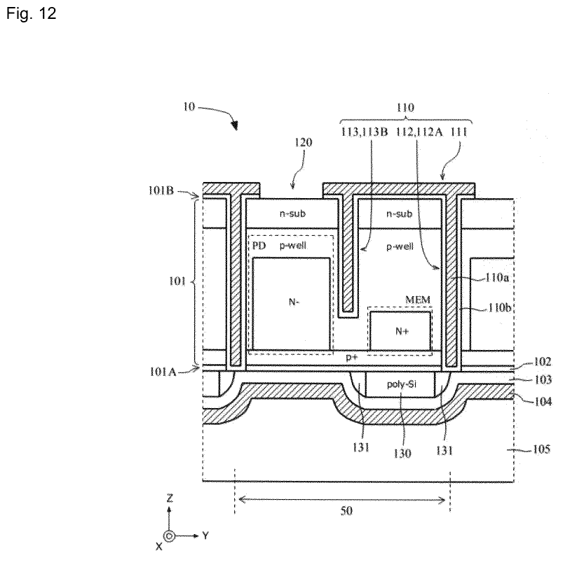

FIG. 12 is a longitudinal cross-sectional view showing the structure of the imaging element 10 of Modified Example 2.

In the imaging element 10 of Modified Example 2, portions of the penetrating portions 112A and 113A of the second and third light-shielding portions 112 and 113 are in contact with the sidewall 131 of the gate 130. More specifically, in the imaging element 10 of Modified Example 2, the ends of the penetrating portions 112A and 113A of the second and third light-shielding portions 112 and 113 on the bottom surface 101A side are not entirely in contact with the sidewall 131, but the ends are partially in contact with the sidewall 131.

In this manner, in the imaging element 10 of the present disclosure, the penetrating portions 112A and 113A of the second and third light-shielding portions 112 and 113 may be partially in contact with the sidewall 131. In this case, it is not necessary to set the width W1 of the sidewall 131 wider than the width W2 at the ends of the penetrating portions 112A and 113A of the second and third light-shielding portions 112 and 113 on the bottom surface 101A side. Therefore, the imaging element 10 of Modified Example 2 has an advantage in that the conventional process for forming the sidewall 131 can be used as is in the manufacturing of the imaging element. However, as in the imaging element 10 of the present embodiment, since the ends of the penetrating portions 112A and 113A of the second and third light-shielding portions 112 and 113 on the bottom surface 101A side are entirely in contact with the sidewall 131, the occurrence of crosstalk between and within the sensor pixels 50 is further suppressed.

### 3. Method for Manufacturing Imaging Element 10 of Present Embodiment

Next, an example of a method for manufacturing the imaging element 10 of the present embodiment will be described.

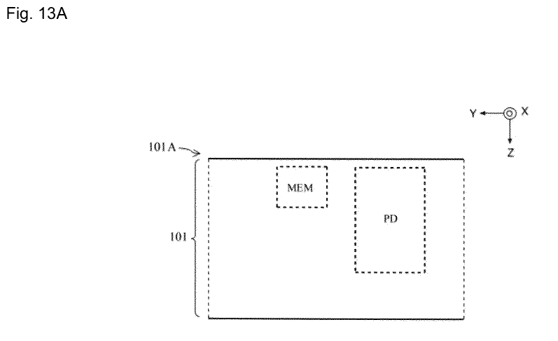

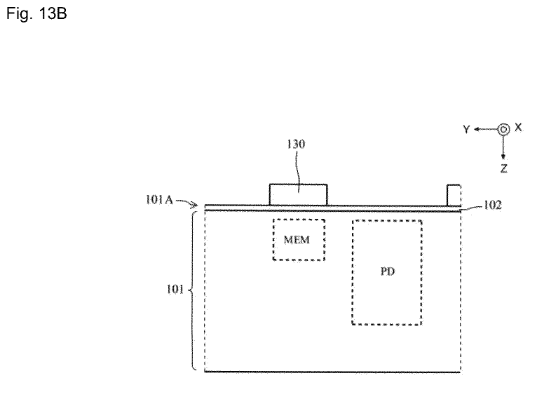

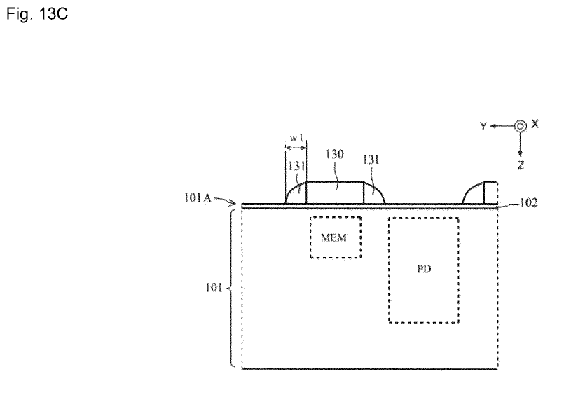

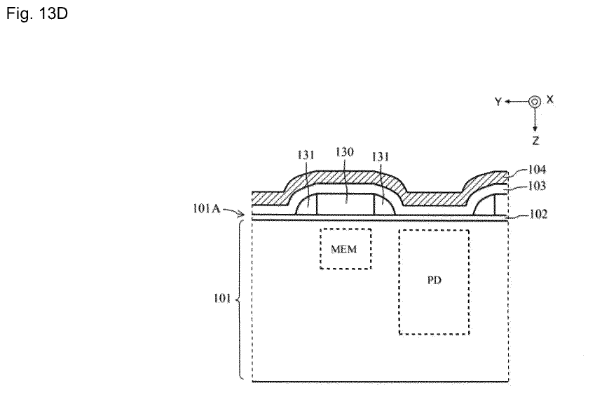

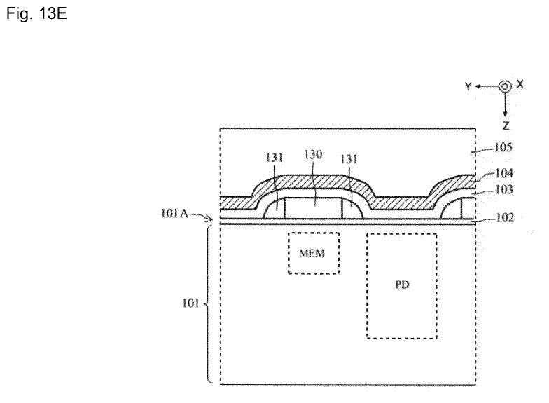

FIGS. 13A to 13E and FIGS. 14A to 14J are longitudinal cross-sectional views showing an example of a method for manufacturing the imaging element 10. FIGS. 13A to 13E show the processing on the bottom surface 101A side of the semiconductor substrate 101, and FIGS. 14A to 14J show the processing on the light-receiving surface 101B side of the semiconductor substrate 101. Therefore, the bottom surface 101A side is arranged on the upper side in FIGS. 13A to 13E, and, conversely, the light-receiving surface 101B side is arranged on the upper side in FIGS. 14A to 14J.

In the processing on the bottom surface 101A side, first, as shown in FIG. 13A, a photoelectric conversion portion PD and a charge holding portion MEM are formed in the semiconductor substrate 101. The photoelectric conversion portion PD and the charge holding portion MEM can be formed by, for example, ion implantation.

Next, as shown in FIG. 13B, after forming an insulating layer 102 on the bottom surface 101A of the semiconductor substrate 101, a gate 130 is formed on the insulating layer 102. The insulating layer 102 can be formed by, for example, thermal oxidation, CVD (Chemical Vaper Deposition), ALD (Atomic Layer Deposition), sputtering, or the like.

Next, as shown in FIG. 13C, sidewalls 131 are formed around the gate 130. At this time, the width W1 of the sidewall 131 is set to be wider than the width W2 (see FIG. 14D) at the bottom of the trench 301T, which will be described later. The width W1 of the sidewall 131 can be adjusted by, for example, the amount of SiN film formed.

Note that in the imaging element 10 of Modified Example 2 described above, the penetrating portions 112A and 113A of the second and third light-shielding portions 112 and 113 are partially in contact with the sidewall 131 of the gate 130. Therefore, it is not necessary to set the width W1 of the sidewall 131 to be wider than the width W2 at the end of the trench 301T on the bottom surface 101A side.

Next, as shown in FIG. 13D, an insulating layer 103 and a light-shielding layer 104 are sequentially stacked on the gate 130 and the insulating layer 102. The insulating layer 103 can be formed by, for example, a CVD method, an ALD method, sputtering, or the like. The light-shielding layer 104 can be formed by, for example, a CVD method, sputtering, or the like.

Next, as shown in FIG. 13E, a wiring layer 105 is formed on the insulating layer 103. The wiring layer 105 is composed of, for example, a plurality of metal layers forming wiring and an insulating layer formed between the metal layers. In this case, the wiring layer 105 is formed by repeatedly forming a metal layer and an insulating layer. This metal layer can be formed, for example, by plating a metal such as copper (Cu) and polishing the plated layer by CMP (Chemical Mechanical Polishing). The insulating layer can be formed by, for example, a CVD method or sputtering.

Finally, although not shown, a support substrate is bonded onto the wiring layer 105, the semiconductor substrate 101 is turned over so that the light-receiving surface 101B side is facing upward, and processing is then proceeded to the light-receiving surface 101B side.

In the processing on the light-receiving surface 101B side, first, as shown in FIG. 14A, the light-receiving surface 101B side of the semiconductor substrate 101 is thinned by CMP or the like. For example, the semiconductor substrate 101 is thinned down to a thickness of 3 μm.

Next, as shown in FIG. 14B, a hard mask 201 is formed on the light-receiving surface 101B to cover regions other than the region where the second and third light-shielding portions 112 and 113 are formed. The hard mask 201 is made of, for example, SIO₂, SiN, or the like. The hard mask 201 can be formed by, for example, stacking SIO₂ and then covering the regions other than the region where the second and third light-shielding portions 112 and 113 are formed with a resistor, and performing anisotropic etching in the region where the second and third light-shielding portions 112 and 113 are formed.

Next, as shown in FIG. 14C, among the regions not covered with the hard mask 201, the region where the non-penetrating portions 112B and 113B of the second and third light-shielding portions 112 and 113 will be formed are covered with a resist 202, and then dry etching is performed. As a result, a trench 301T that does not penetrate the semiconductor substrate 101 but extends halfway in the thickness direction of the semiconductor substrate 101 is formed in the region where the penetrating portions 112A and 113A are formed.

Next, as shown in FIG. 14D, after removing the resist 202 that blocks the region where the non-penetrating portions 112B and 113B are to be formed, dry etching is further performed. As a result, the above-mentioned trench 301T is made to penetrate the semiconductor substrate 101, and the trench 302T that does not penetrate the semiconductor substrate 101 but extends halfway in the thickness direction of the semiconductor substrate 101 is formed in the region where the non-penetrating portions 112B and 113B are formed.

At this time, the etching of the trench 301T penetrating the semiconductor substrate 101 is stopped by the sidewall 131 of the gate 130, which functions as an etching stopper. In order to function as such an etching stopper, the sidewall 131 is located below the trench 301T penetrating the semiconductor substrate 101, and its width W1 is wider than the width W2 of the end of the trench 301T on the bottom surface 101A side.

In this way, by using the sidewall 131 as an etching stopper, the in-plane uniformity of the processing depth of the trench 301T becomes excellent. In this way, the processing margin is expanded and the trench 301T can be easily formed.

Note that in the imaging element 10 of Modified Examples 1 and 2 described above, all or part of the trench 301T that penetrates the semiconductor substrate 101 deviates from the sidewall 131 and comes into contact with the insulating layer 103. Therefore, in the imaging element 10 of Modified Examples 1 and 2, the insulating layer 103 has a function as an etching stopper.

Next, as shown in FIG. 14E, a resist 203 is embedded in the trenches 301T and 302T in order to protect the trenches 301T and 302T in the subsequent process of removing the hard mask 201. The resist 203 can be embedded into the trenches 301T and 302T, for example, by coating the semiconductor substrate 101 with the resist 203 so as to fill the trenches 301T and 302T, and then performing etchback.

Next, as shown in FIG. 14F, the hard mask 201 is removed. The hard mask 201 can be removed, for example, by wet etching.

Next, as shown in FIG. 14G, the resist 203 embedded in the trenches 301T and 302T is removed. The resist 203 embedded in the trenches 301T and 302T can be removed by, for example, SH cleaning.

Next, as shown in FIG. 14H, an insulating film 110b is formed to cover the inner surfaces of the trenches 301T and 302T and the light-receiving surface 101B. The insulating film 110b can be formed, for example, by depositing SiO₂ (silicon oxide) using an ALD (Atomic Layer Deposition) method.

Next, as shown in FIG. 13I, a light-shielding material portion 110a of the light-shielding portion 110 is formed by embedding a light-shielding material constituting the light-shielding material portion 101a in the trenches 301T and 302T in which the insulating film 110b is formed, and stacking the light-shielding material on the light-receiving surface 101B. The embedding and stacking of the light-shielding material can be achieved by, for example, the CVD method.

Next, as shown in FIG. 14J, the opening 120 is formed by removing the light-shielding material portion 110a and the insulating film 101b in the region where the opening 120 is to be formed. The light-shielding material portion 110a and the insulating film 101b can be removed by wet etching, for example.

At this time, in order to reduce etching damage caused to the peripheral regions of the sidewalls of the second and third light-shielding portions 112 and 113, the region of the opening 120 is set so that the ends on the light-receiving surface 101B side of the second and third light-shielding portions 112 and 113 are spaced apart from the opening 120. More preferably, the distance d1 from the opening 120 to the end of the second light-shielding portion 112 on the light-receiving surface 101B side is set to be 50 nm or more. Furthermore, the distance d2 from the opening 120 to the end of the third light-shielding portion 113 on the light-receiving surface 101B side is set to be 50 nm or more.

Finally, the insulating layer 106, color filter 107, and microlens 108 are sequentially stacked on the light-receiving surface 101B (see FIG. 4).

To summarize the above, the method for manufacturing the imaging element 10 of the present embodiment includes a photoelectric conversion portion forming step of forming the photoelectric conversion portion PD in the semiconductor substrate 101, a charge holding portion forming step of forming the charge holding portion MEM in the semiconductor substrate 101, a gate forming step of forming the gates 130 of the transfer transistors TRX, TRY, and TRG on a region of the bottom surface 101A of the semiconductor substrate 101, the region overlapping the charge holding portion MEM, a sidewall forming step of forming the sidewall 131 around the gates 130, and an in-substrate-shielding portion forming step of forming the second light-shielding portion (in-substrate-shielding portion) 112 in the boundary region of the sensor pixel 50 in the semiconductor substrate 101. The second light-shielding portion (in-substrate-shielding portion) 112 has the penetrating portion 112A that penetrates the semiconductor substrate 101, and is in contact with the sidewall 130 at the penetrating portion 112A.

According to such a method for manufacturing the imaging element 10, it is possible to manufacture the imaging element 10 in which the generation of optical noise is suppressed.

Further, in the method for manufacturing the imaging element 10 of the present embodiment, the above-described in-substrate-shielding portion forming step includes a trench forming step of forming the trench 301T by etching using the sidewall 131 as an etching stopper.

According to such a method for manufacturing the imaging element 10, it becomes possible to easily form the penetrating portion 112A of the second light-shielding portion 112 that penetrates the semiconductor substrate 101.

Further, the method for manufacturing the imaging element 10 of the present embodiment includes a light-receiving-surface-shielding portion forming step of forming the first light-shielding portion (light-receiving-surface-shielding portion) 111 that covers the light-receiving surface 101B, and an opening forming step of forming the opening 120 in a region overlapping the photoelectric conversion portion PD of the first light-shielding portion (light-receiving-surface-shielding portion) 111. The opening forming step forms the opening 120 so that the end of the second light-shielding portion (in-substrate-shielding portion) 112 on the light-receiving surface 101B side is spaced apart from the opening 120.

According to such a method for manufacturing the imaging element 10, it is possible to manufacture the imaging element 10 in which the occurrence of white spots is suppressed.

### 4. Example of Application to Electronic Device

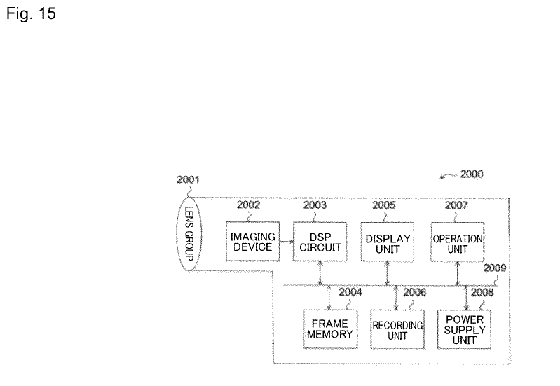

FIG. 15 is a block diagram showing a configuration example of a camera 2000 as an electronic device to which the technology according to the present disclosure is applied.

The camera 2000 includes an optical unit 2001 including a lens group, an imaging device 2002 to which the above-described imaging element 10 or the like is applied, and a DSP (Digital Signal Processor) circuit 2003, which is a camera signal processing circuit. The camera 2000 further includes a frame memory 2004, a display unit 2005, a recording unit 2006, an operation unit 2007, and a power supply unit 2008. The DSP circuit 2003, frame memory 2004, display unit 2005, recording unit 2006, operation unit 2007, and power supply unit 2008 are interconnected via a bus line 2009.

The optical unit 2001 captures incident light (image light) from a subject and forms an image on an imaging surface of the imaging device 2002. The imaging device 2002 converts the amount of incident light formed onto the imaging surface by the optical unit 2001 into an electrical signal for each pixel, and outputs the electric signal as a pixel signal.

The display unit 2005 is composed of a panel display device such as a liquid crystal panel or an organic EL panel, and displays a moving image or a still image captured by the imaging device 2002. The recording unit 2006 records a moving image or a still image captured by the imaging device 2002 on a recording medium such as a hard disk or a semiconductor memory.

The operation unit 2007 issues operation commands for various functions that the camera 2000 has in response to user operations. The power supply unit 2008 appropriately supplies various power supplies that serve as operating power for the DSP circuit 2003, frame memory 2004, display unit 2005, recording unit 2006, and operation unit 2007 to these supply targets.

As described above, by using the above-described imaging element 10 or the like as the imaging device 2002, it is possible to obtain good images.

### 5. Example of Application to Mobile Object

The technology according to the present disclosure can be applied to various products. For example, the technology according to the present disclosure may be realized as a device equipped in any type of moving body such as an automobile, an electric vehicle, a hybrid electric vehicle, a motorcycle, a bicycle, a personal mobility device, an airplane, a drone, a ship, and a robot.

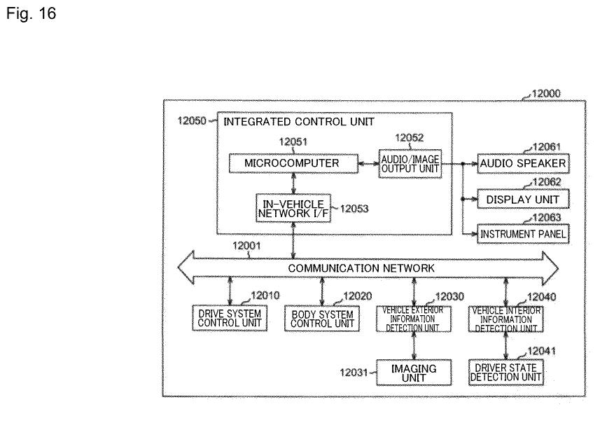

FIG. 16 is a block diagram illustrating a schematic configuration example of a vehicle control system 12000 which is an example of a moving body control system to which the technology according to the present disclosure can be applied.

The vehicle control system 12000 includes a plurality of electronic control units connected to each other via a communication network 12001. In the example illustrated in FIG. 16, the vehicle control system 12000 includes a drive system control unit 12010, a body system control unit 12020, a vehicle exterior information detection unit 12030, a vehicle interior information detection unit 12040, and an integrated control unit 12050. As a functional configuration of the integrated control unit 12050, a microcomputer 12051, an audio/image output unit 12052, and an in-vehicle network I/F (interface) 12053 are illustrated.

The drive system control unit 12010 controls the operation of the device related to the drive system of the vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control device such as a braking device that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a headlamp, a back lamp, a brake lamp, a turn signal, and a fog lamp. In this case, radio waves transmitted from a portable device that substitutes for a key or signals of various switches may be input to the body system control unit 12020. The body system control unit 12020 receives inputs of the radio waves or signals and controls a door lock device, a power window device, and a lamp of the vehicle.

The vehicle exterior information detection unit 12030 detects information on the outside of the vehicle having the vehicle control system 12000 mounted thereon. For example, an imaging unit 12031 is connected to the vehicle exterior information detection unit 12030. The vehicle exterior information detection unit 12030 causes the imaging unit 12031 to capture an image of the outside of the vehicle and receives the captured image. The vehicle exterior information detection unit 12030 may perform object detection processing or distance detection processing for peoples, cars, obstacles, signs, and letters on the road on the basis of the received image.

The imaging unit 12031 is an optical sensor that receives light and outputs an electrical signal according to the amount of the received light. The imaging unit 12031 can also output the electrical signal as an image or distance measurement information. In addition, the light received by the imaging unit 12031 may be visible light or invisible light such as infrared light.

The vehicle interior information detection unit 12040 detects information on the inside of the vehicle. For example, a driver state detection unit 12041 that detects a driver's state is connected to the vehicle interior information detection unit 12040. The driver state detection unit 12041 includes, for example, a camera that captures an image of a driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of the information on the outside or the inside of the vehicle acquired by the vehicle exterior information detection unit 12030 or the vehicle interior information detection unit 12040 and output a control command to the drive system control unit 12010. For example, the microcomputer 12051 can perform cooperative control for the purpose of realizing functions of an advanced driver assistance system (ADAS) including collision avoidance or impact mitigation of a vehicle, following traveling based on inter-vehicle distance, vehicle speed maintenance driving, vehicle collision warning, vehicle lane deviation warning, or the like.

Further, the microcomputer 12051 can perform cooperative control for the purpose of automated driving or the like in which autonomous travel is performed without depending on operations of the driver, by controlling the driving force generator, the steering mechanism, or the braking device and the like on the basis of information about the surroundings of the vehicle, the information being acquired by the vehicle exterior information detection unit 12030 or the vehicle interior information detection unit 12040.

In addition, the microcomputer 12051 can output a control command to the body system control unit 12020 based on the information acquired by the vehicle exterior information detection unit 12030 outside the vehicle. For example, the microcomputer 12051 can perform cooperative control for the purpose of preventing glare, such as switching from a high beam to a low beam, by controlling the headlamp according to the position of a preceding vehicle or an oncoming vehicle detected by the vehicle exterior information detection unit 12030.

The audio/image output unit 12052 transmits an output signal of at least one of sound and an image to an output device capable of visually or audibly notifying a passenger or the outside of the vehicle of information. In the example of FIG. 16, an audio speaker 12061, a display unit 12062, and an instrument panel 12063 are illustrated as the output device. The display unit 12062 may include, for example, at least one of an on-board display and a heads-up display.

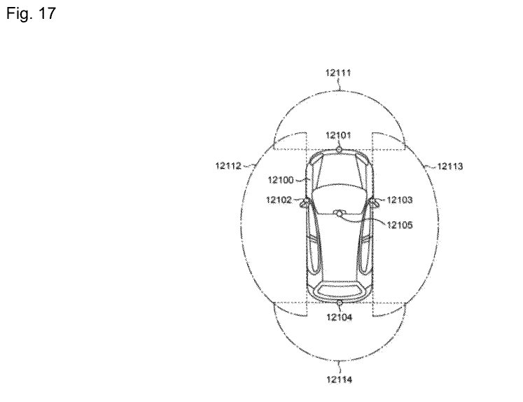

FIG. 17 is a diagram illustrating an example of an installation position of the imaging unit 12031.

In FIG. 17, the imaging unit 12031 includes imaging units 12101, 12102, 12103, 12104, and 12105.

The imaging units 12101, 12102, 12103, 12104, and 12105 are provided at, for example, positions of a front nose, side mirrors, a rear bumper, a back door, an upper portion of a vehicle internal front windshield, and the like of the vehicle 12100. The imaging unit 12101 provided on a front nose and the imaging unit 12105 provided in an upper portion of the vehicle internal front windshield mainly acquire images in front of the vehicle 12100. The imaging units 12102 and 12103 provided in the side mirrors mainly acquire images on the lateral sides of the vehicle 12100. The imaging unit 12104 included in the rear bumper or the back door mainly acquires an image of a region behind the vehicle 12100. The imaging unit 12105 included in the upper portion of the windshield inside the vehicle is mainly used for detection of a preceding vehicle, a pedestrian, an obstacle, a traffic signal, a traffic sign, a lane, or the like.

FIG. 17 illustrates an example of imaging ranges of the imaging units 12101 to 12104. An imaging range 12111 indicates an imaging range of the imaging unit 12101 provided at the front nose, imaging ranges 12112 and 12113 respectively indicate the imaging ranges of the imaging units 12102 and 12103 provided at the side-view mirrors, and an imaging range 12114 indicates the imaging range of the imaging unit 12104 provided at the rear bumper or the back door. For example, by superimposing image data captured by the imaging units 12101 to 12104, it is possible to obtain a bird's-eye view image viewed from the upper side of the vehicle 12100.

At least one of the imaging units 12101 to 12104 may have a function for obtaining distance information. For example, at least one of the imaging units 12101 to 12104 may be a stereo camera constituted by a plurality of imaging elements or may be an imaging element that has pixels for phase difference detection.

For example, the microcomputer 12051 can extract, particularly, a closest three-dimensional object on a path along which the vehicle 12100 is traveling, which is a three-dimensional object traveling at a predetermined speed (for example, 0 km/h or higher) in the substantially same direction as the vehicle 12100, as a vehicle ahead by acquiring a distance to each three-dimensional object in the imaging ranges 12111 to 12114 and a temporal change of the distance (a relative speed with respect to the vehicle 12100) on the basis of the distance information obtained from the imaging units 12101 to 12104. Furthermore, the microcomputer 12051 can set an inter-vehicle distance to be secured from a vehicle ahead in advance with respect to the vehicle ahead and can perform automated brake control (also including following stop control) or automated acceleration control (also including following start control). In this way, cooperative control can be performed for the purpose of automated driving or the like in which a vehicle autonomously travels without depending on the operations of the driver.

For example, the microcomputer 12051 can classify and extract three-dimensional data regarding three-dimensional objects into two-wheeled vehicles, normal vehicles, large vehicles, pedestrians, and other three-dimensional objects such as electric poles based on distance information obtained from the imaging units 12101 to 12104 and can use the three-dimensional data to perform automated avoidance of obstacles. For example, the microcomputer 12051 differentiates surrounding obstacles of the vehicle 12100 into obstacles which can be viewed by the driver of the vehicle 12100 and obstacles which are difficult to view. Then, the microcomputer 12051 determines a collision risk indicating the degree of risk of collision with each obstacle, and when the collision risk is equal to or higher than a set value and there is a possibility of collision, an alarm is output to the driver through the audio speaker 12061 or the display unit 12062, forced deceleration or avoidance steering is performed through the drive system control unit 12010, and thus it is possible to perform driving support for collision avoidance.

At least one of the imaging units 12101 to 12104 may be an infrared camera that detects infrared rays. For example, the microcomputer 12051 can recognize a pedestrian by determining whether there is a pedestrian in the captured image of the imaging units 12101 to 12104. Such pedestrian recognition is performed by, for example, a procedure in which feature points in the captured images of the imaging units 12101 to 12104 as infrared cameras are extracted and a procedure in which pattern matching processing is performed on a series of feature points indicating an outline of an object to determine whether or not the object is a pedestrian. When the microcomputer 12051 determines that there is a pedestrian in the captured images of the imaging units 12101 to 12104 and the pedestrian is recognized, the audio/image output unit 12052 controls the display unit 12062 so that a square contour line for emphasis is superimposed and displayed with the recognized pedestrian. In addition, the audio/image output unit 12052 may control the display unit 12062 so that an icon indicating a pedestrian or the like is displayed at a desired position.

An example of the vehicle control system to which the technology according to the present disclosure can be applied has been described above. The technology according to the present disclosure can be applied to the imaging unit 12031 within the configuration described above. Specifically, the imaging element 10 and the like illustrated in FIG. 1 and the like can be applied to the imaging unit 12031. It is possible to expect excellent operations of the vehicle control system by applying the technology according to the present disclosure to the imaging unit 12031.

### 6. Example of Application to Endoscopic Surgery System

For example, the technology according to the present disclosure (present technology) may be applied to an endoscopic surgery system.

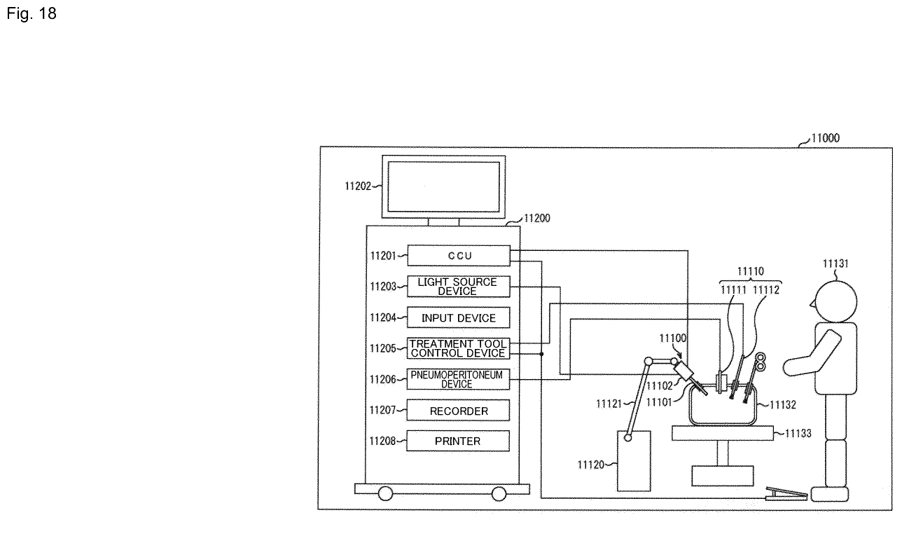

FIG. 18 is a diagram illustrating an example of a schematic configuration of an endoscopic surgery system to which the technology according to the present disclosure (the present technology) is applied.

FIG. 18 shows a state where an operator (doctor) 11131 is using an endoscopic surgery system 11000 to perform a surgical operation on a patient 11132 on a patient bed 11133. As illustrated, the endoscopic surgery system 11000 is constituted of an endoscope 11100, another surgical instrument 11110 such as a pneumoperitoneum tube 11111 or an energy treatment tool 11112, a support arm device 11120 that supports the endoscope 11100, and a cart 11200 mounted with various devices for endoscopic surgery.

The endoscope 11100 includes a lens barrel 11101 of which a region having a predetermined length from a tip thereof is inserted into a body cavity of the patient 11132, and a camera head 11102 connected to a base end of the lens barrel 11101. In the illustrated example, the endoscope 11100 configured as a so-called rigid endoscope having the rigid lens barrel 11101 is illustrated, but the endoscope 11100 may be configured as a so-called flexible endoscope having a flexible lens barrel.

The distal end of the lens barrel 11101 is provided with an opening into which an objective lens is fitted. A light source device 11203 is connected to the endoscope 11100, light generated by the light source device 11203 is guided to the distal end of the lens barrel 11101 by a light guide extended to the inside of the lens barrel 11101, and the light is radiated toward an observation target in the body cavity of the patient 11132 through the objective lens. The endoscope 11100 may be a direct-viewing endoscope, an oblique-viewing endoscope, or a side-viewing endoscope.

An optical system and an imaging element are provided inside the camera head 11102, and the reflected light (observation light) from the observation target converges on the imaging element by the optical system. The observation light is photoelectrically converted by the imaging element, and an electrical signal corresponding to the observation light, that is, an image signal corresponding to an observation image is generated. The image signal is transmitted to a camera control unit (CCU) 11201 as RAW data.

The CCU 11201 is constituted by a central processing unit (CPU), a graphics processing unit (GPU), and the like and comprehensively controls the operation of the endoscope 11100 and a display device 11202. In addition, the CCU 11201 receives an image signal from the camera head 11102 and performs various types of image processing for displaying an image based on the image signal, for example, development processing (demosaic processing) on the image signal.

The display device 11202 displays the image based on the image signal subjected to the image processing by the CCU 11201 under the control of the CCU 11201.

The light source device 11203 is constituted of, for example, a light source such as an LED (Light Emitting Diode) and supplies the endoscope 11100 with irradiation light when photographing a surgical site or the like.

An input device 11204 is an input interface for the endoscopic surgery system 11000. The user can input various types of information or instructions to the endoscopic surgery system 11000 via the input device 11204. For example, the user inputs an instruction to change imaging conditions (a type of radiation light, a magnification, a focal length, or the like) of the endoscope 11100.

A treatment tool control device 11205 controls driving of the energy treatment tool 11112 for cauterization or incision of a tissue, sealing of blood vessel, or the like. A pneumoperitoneum device 11206 sends a gas into the body cavity of the patient 11132 via the pneumoperitoneum tube 11111 in order to inflate the body cavity for the purpose of securing a field of view using the endoscope 11100 and a working space of the surgeon. A recorder 11207 is a device capable of recording various types of information on surgery. A printer 11208 is a device capable of printing various types of information on surgery in various formats such as text, images, and graphs.

The light source device 11203 that supplies the endoscope 11100 with the radiation light for imaging the surgical site can be configured of, for example, an LED, a laser light source, or a white light source configured of a combination thereof. When a white light source is formed by a combination of RGB laser light sources, it is possible to control an output intensity and an output timing of each color (each wavelength) with high accuracy, and thus the light source device 11203 can adjust white balance of the captured image. Further, in this case, laser light from each of the respective RGB laser light sources is radiated to the observation target in a time division manner, and driving of the imaging element of the camera head 11102 is controlled in synchronization with radiation timing such that images corresponding to respective RGB can be captured in a time division manner. According to this method, it is possible to obtain a color image without providing a color filter in the imaging element.

Further, driving of the light source device 11203 may be controlled so that an intensity of output light is changed at predetermined time intervals. The driving of the imaging element of the camera head 11102 is controlled in synchronization with a timing of changing the intensity of the light, and images are acquired in a time division manner and combined, such that an image having a high dynamic range without so-called blackout and whiteout can be generated.

In addition, the light source device 11203 may have a configuration in which light in a predetermined wavelength band corresponding to special light observation can be supplied. In the special light observation, for example, by emitting light in a band narrower than that of radiation light (that is, white light) during normal observation using wavelength dependence of light absorption in a body tissue, so-called narrow band light observation (narrow band imaging) in which a predetermined tissue such as a blood vessel in a mucous membrane surface layer is imaged with a high contrast is performed. Alternatively, in the special light observation, fluorescence observation in which an image is obtained by fluorescence generated by emitting excitation light may be performed. The fluorescence observation can be performed by emitting excitation light to a body tissue and observing fluorescence from the body tissue (autofluorescence observation), or locally injecting a reagent such as indocyanine green (ICG) to a body tissue and emitting excitation light corresponding to a fluorescence wavelength of the reagent to the body tissue to obtain a fluorescence image. The light source device 11203 may have a configuration in which narrow band light and/or excitation light corresponding to such special light observation can be supplied.

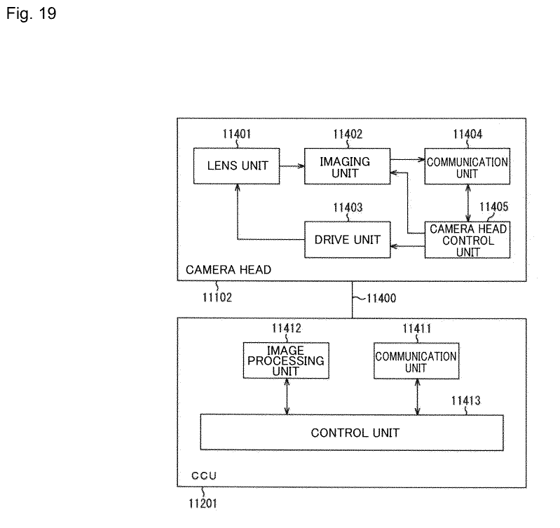

FIG. 19 is a block diagram illustrating an example of a functional configuration of the camera head 11102 and CCU 11201 illustrated in FIG. 18.

The camera head 11102 includes a lens unit 11401, an imaging unit 11402, a drive unit 11403, a communication unit 11404, and a camera head control unit 11405. The CCU 11201 has a communication unit 11411, an image processing unit 11412, and a control unit 11413. The camera head 11102 and the CCU 11201 are communicatively connected to each other by a transmission cable 11400.

The lens unit 11401 is an optical system provided in a connection portion for connection to the lens barrel 11101. Observation light taken from a tip of the lens barrel 11101 is guided to the camera head 11102 and is incident on the lens unit 11401. The lens unit 11401 is configured in combination of a plurality of lenses including a zoom lens and a focus lens.

The imaging unit 11402 is constituted by an imaging element. The imaging element constituting the imaging unit 11402 may be one element (a so-called single plate type) or a plurality of elements (a so-called multi-plate type). When the imaging unit 11402 is configured as a multi-plate type, for example, image signals corresponding to RGB are generated by the imaging elements, and a color image may be obtained by synthesizing the image signals. Alternatively, the imaging unit 11402 may be configured to include a pair of imaging elements for acquiring image signals for the right eye and the left eye corresponding to three-dimensional (3D) display. When 3D display is performed, the operator 11131 can ascertain the depth of biological tissues in the surgical site more accurately. When the imaging unit 11402 is configured in a multi-plate type, a plurality of systems of lens units 11401 may be provided in correspondence to the imaging elements.

The imaging unit 11402 need not necessarily be provided in the camera head 11102. For example, the imaging unit 11402 may be provided immediately after the objective lens inside the lens barrel 11101.

The drive unit 11403 is configured by an actuator and the zoom lens and the focus lens of the lens unit 11401 are moved by a predetermined distance along an optical axis under the control of the camera head control unit 11405. Accordingly, the magnification and focus of the image captured by the imaging unit 11402 can be adjusted appropriately.

The communication unit 11404 is configured using a communication device for transmitting and receiving various types of information to and from the CCU 11201. The communication unit 11404 transmits the image signal obtained from the imaging unit 11402 as RAW data to the CCU 11201 via the transmission cable 11400.

The communication unit 11404 receives a control signal for controlling driving of the camera head 11102 from the CCU 11201 and supplies the camera head control unit 11405 with the control signal. The control signal includes, for example, information regarding imaging conditions such as information indicating designation of a frame rate of a captured image, information indicating designation of an exposure value at the time of imaging, and/or information indicating designation of a magnification and a focus of the captured image.

The imaging conditions such as the frame rate, the exposure value, the magnification, and the focus may be appropriately designated by the user, or may be automatically set by the control unit 11413 of the CCU 11201 on the basis of the acquired image signal. In the latter case, a so-called auto exposure (AE) function, a so-called auto focus (AF) function, and a so-called auto white balance (AWB) function are provided in the endoscope 11100.

The camera head control unit 11405 controls driving of the camera head 11102 on the basis of a control signal from the CCU 11201 received via the communication unit 11404.

The communication unit 11411 is constituted of a communication device that transmits and receives various kinds of information to and from the camera head 11102. The communication unit 11411 receives an image signal transmitted via the transmission cable 11400 from the camera head 11102.

Further, the communication unit 11411 transmits the control signal for controlling the driving of the camera head 11102 to the camera head 11102. The image signal or the control signal can be transmitted through electric communication, optical communication, or the like.

The image processing unit 11412 performs various types of image processing on the image signal that is the RAW data transmitted from the camera head 11102.

The control unit 11413 performs various kinds of control on imaging of a surgical site by the endoscope 11100, display of a captured image obtained through imaging of a surgical site, or the like. For example, the control unit 11413 generates a control signal for controlling driving of the camera head 11102.

In addition, the control unit 11413 causes the display device 11202 to display a captured image showing a surgical site or the like based on an image signal subjected to the image processing by the image processing unit 11412. In doing so, the control unit 11413 may recognize various objects in the captured image using various image recognition techniques. For example, the control unit 11413 can recognize a surgical instrument such as forceps, a specific biological site, bleeding, mist or the like at the time of use of the energy treatment tool 11112, or the like by detecting a shape, a color, or the like of an edge of an object included in the captured image. When the display device 11202 is caused to display a captured image, the control unit 11413 may superimpose various kinds of surgery support information on an image of the surgical site for display using a recognition result of the captured image. By displaying the surgery support information in a superimposed manner and presenting it to the operator 11131, a burden on the operator 11131 can be reduced, and the operator 11131 can reliably proceed with the surgery.

The transmission cable 11400 that connects the camera head 11102 and the CCU 11201 is an electrical signal cable compatible with communication of electrical signals, an optical fiber compatible with optical communication, or a composite cable of these.

Here, although wired communication is performed using the transmission cable 11400 in the illustrated example, communication between the camera head 11102 and the CCU 11201 may be performed wirelessly.

An example of the endoscopic surgery system to which the technique according to the present disclosure can be applied has been described above. The technology according to the present disclosure may be applied, for example, to the imaging unit 11402 among the configurations described above. Specifically, the imaging element 10 and the like illustrated in FIG. 1 and the like can be applied to the imaging unit 11402. By applying the technology according to the present disclosure to the imaging unit 11402, a clearer image of the surgical site can be obtained, and thus it is possible for the surgeon to reliably check the surgical site.

Here, although the endoscopic surgery system has been described as an example, the technology according to the present disclosure may be applied to other, for example, a microscopic surgery system.

### 7. Summary

Although an example of the embodiment of the present disclosure has been described above, the present disclosure can be implemented in various other forms. For example, various modified examples, substitutions, omissions, or combinations thereof are possible without departing from the gist of the present disclosure. Such forms of modified examples, substitutions, and omissions are included in the scope of the invention described in the claims and the scope of equivalence thereof, as included in the scope of the present disclosure.

In addition, the effects of the present disclosure described herein are merely exemplary and may have other effects.

Note that the present disclosure may also be configured as follows.

### [Item 1]

An imaging element comprising:
a semiconductor substrate;
a photoelectric conversion portion disposed in the semiconductor substrate to generate charges according to an amount of received light through photoelectric conversion;
a charge holding portion disposed in the semiconductor substrate to hold charges transferred from the photoelectric conversion portion;
a gate of a transfer transistor disposed on a region of a bottom surface of the semiconductor substrate, the region overlapping the charge holding portion;
a sidewall formed around the gate; and
an in-substrate-shielding portion that is a light-shielding portion disposed in a boundary region of sensor pixels in the semiconductor substrate to extend from a light-receiving surface of the semiconductor substrate toward the bottom surface side, wherein
the in-substrate-shielding portion has a penetrating portion that penetrates the semiconductor substrate, and is in contact with the sidewall at the penetrating portion.

### [Item 2]

The imaging element according to item 1, wherein
a width of the sidewall is wider than a width of an end on the bottom surface side of the penetrating portion.

### [Item 3]

The imaging element according to item 1 or 2, further comprising
a light-receiving-surface-shielding portion that is a light-shielding portion that covers the light-receiving surface of the semiconductor substrate, wherein
the light-receiving-surface-shielding portion has an opening formed in a region overlapping the photoelectric conversion portion, and
an end of the in-substrate-shielding portion on the light-receiving surface side is spaced apart from the opening.

### [Item 4]

The imaging element according to item 3, wherein
a distance from the opening to the end of the light-receiving surface side of the in-substrate-shielding portion is 50 nm or more.

### [Item 5]

The imaging element according to any one of items 1 to 5, wherein
the imaging element is a global shutter-type back-illuminated image sensor.

### [Item 6]

A method for manufacturing an imaging element, comprising:
a photoelectric conversion portion forming step of forming a photoelectric conversion portion disposed in a semiconductor substrate to generate charges according to an amount of received light through photoelectric conversion;
a charge holding portion forming step of forming a charge holding portion disposed in the semiconductor substrate to hold charges transferred from the photoelectric conversion portion;
a gate forming step of forming a gate of a transfer transistor disposed on a region of a bottom surface of the semiconductor substrate, the region overlapping the charge holding portion;
a sidewall forming step of forming a sidewall around the gate; and an in-substrate-shielding portion forming step of forming an in-substrate-shielding portion that is a light-shielding portion disposed in a boundary region of sensor pixels in the semiconductor substrate to extend from a light-receiving surface of the semiconductor substrate toward the bottom surface side, wherein
the in-substrate-shielding portion has a penetrating portion that penetrates the semiconductor substrate, and is in contact with the sidewall at the penetrating portion.

### [Item 7]

The method for manufacturing the imaging element according to item 6, comprising:
the in-substrate-shielding portion forming step includes a trench forming step of forming a trench by etching using the sidewall as an etching stopper.

### [Item 8]

The method for manufacturing the imaging element according to item 6 or 7, further comprising:
a light-receiving-surface-shielding portion forming step of forming a light-receiving-surface-shielding portion that is a light-shielding portion that covers the light-receiving surface; and
an opening forming step of forming an opening in a region of the light-receiving-surface-shielding portion, the region overlapping the photoelectric conversion portion, wherein
in the opening forming step, the opening is formed such that an end of the in-substrate-shielding portion on the light-receiving surface side is spaced apart from the opening.

### [Item 9]

An electronic device equipped with an imaging element,
the imaging element comprising:
a semiconductor substrate;
a photoelectric conversion portion disposed in the semiconductor substrate to generate charges according to an amount of received light through photoelectric conversion;
a charge holding portion disposed in the semiconductor substrate to hold charges transferred from the photoelectric conversion portion;
a gate of a transfer transistor disposed on a region of a bottom surface of the semiconductor substrate, the region overlapping the charge holding portion;
a sidewall formed around the gate; and
an in-substrate-shielding portion that is a light-shielding portion disposed in a boundary region of sensor pixels in the semiconductor substrate to extend from a light-receiving surface of the semiconductor substrate toward the bottom surface side, wherein
the in-substrate-shielding portion has a penetrating portion that penetrates the semiconductor substrate, and is in contact with the sidewall at the penetrating portion.

### REFERENCE SIGNS LIST

10 Imaging element
11 Pixel array unit
12 Vertical drive unit
13 Column signal processing unit
14 Horizontal drive unit
15 System control unit
16 Signal processing unit
17 Pixel drive line
18 Vertical signal line
50 Sensor pixel
101 Semiconductor substrate
102, 103, 106 Insulating layer
104 Light-shielding layer
105 Wiring layer
107 Color filter
108 Microlens
110 Light-shielding portion,
110a Light-shielding material portion,
110b Insulating film
111 First light-shielding portion (light-receiving-surface-shielding portion)
112 Second light-shielding portion (in-substrate-shielding portion),
112A Penetrating portion,
112B Non-penetrating portion
113 Third light-shielding portion (in-substrate-shielding portion),
113A Penetrating portion,
113B Non-penetrating portion
120 Opening
130 Gate
131 Sidewall
201 Hard mask
202, 203 Resist
301T Trench (penetrating portion)
302T Trench (non-penetrating portion)
PD Photoelectric conversion portion
MEM Charge holding portion
TRX, TRY, TRGTransfer transistor
FD Floating diffusion region
OFG Discharge transistor
RST Reset transistor
AMP Amplification transistor
SEL Selection transistor
VDD Power supply line
VSL Vertical signal line

1. An imaging element comprising:
a semiconductor substrate;
a photoelectric conversion portion disposed in the semiconductor substrate to generate charges according to an amount of received light through photoelectric conversion;
a charge holding portion disposed in the semiconductor substrate to hold charges transferred from the photoelectric conversion portion;
a gate of a transfer transistor disposed on a region of a bottom surface of the semiconductor substrate, the region overlapping the charge holding portion;
a sidewall formed around the gate; and
an in-substrate-shielding portion that is a light-shielding portion disposed in a boundary region of sensor pixels in the semiconductor substrate to extend from a light-receiving surface of the semiconductor substrate toward the bottom surface side, wherein
the in-substrate-shielding portion has a penetrating portion that penetrates the semiconductor substrate, and is in contact with the sidewall at the penetrating portion.

2. The imaging element according to claim 1, wherein
a width of the sidewall is wider than a width of an end on the bottom surface side of the penetrating portion.

3. The imaging element according to claim 1, further comprising
a light-receiving-surface-shielding portion that is a light-shielding portion that covers the light-receiving surface of the semiconductor substrate, wherein
the light-receiving-surface-shielding portion has an opening formed in a region overlapping the photoelectric conversion portion, and
an end of the in-substrate-shielding portion on the light-receiving surface side is spaced apart from the opening.

4. The imaging element according to claim 3, wherein
a distance from the opening to the end of the light-receiving surface side of the in-substrate-shielding portion is 50 nm or more.

5. The imaging element according to claim 1, wherein
the imaging element is a global shutter-type back-illuminated image sensor.

6. A method for manufacturing an imaging element, comprising:
a photoelectric conversion portion forming step of forming a photoelectric conversion portion disposed in a semiconductor substrate to generate charges according to an amount of received light through photoelectric conversion;
a charge holding portion forming step of forming a charge holding portion disposed in the semiconductor substrate to hold charges transferred from the photoelectric conversion portion;
a gate forming step of forming a gate of a transfer transistor disposed on a region of a bottom surface of the semiconductor substrate, the region overlapping the charge holding portion;
a sidewall forming step of forming a sidewall around the gate; and
an in-substrate-shielding portion forming step of forming an in-substrate-shielding portion that is a light-shielding portion disposed in a boundary region of sensor pixels in the semiconductor substrate to extend from a light-receiving surface of the semiconductor substrate toward the bottom surface side, wherein
the in-substrate-shielding portion has a penetrating portion that penetrates the semiconductor substrate, and is in contact with the sidewall at the penetrating portion.

7. The method for manufacturing the imaging element according to claim 6, comprising:
the in-substrate-shielding portion forming step includes a trench forming step of forming a trench by etching using the sidewall as an etching stopper.

8. The method for manufacturing the imaging element according to claim 6, further comprising:
a light-receiving-surface-shielding portion forming step of forming a light-receiving-surface-shielding portion that is a light-shielding portion that covers the light-receiving surface; and
an opening forming step of forming an opening in a region of the light-receiving-surface-shielding portion, the region overlapping the photoelectric conversion portion, wherein
in the opening forming step, the opening is formed such that an end of the in-substrate-shielding portion on the light-receiving surface side is spaced apart from the opening.

9. An electronic device equipped with an imaging element,
the imaging element comprising:
a semiconductor substrate;
a photoelectric conversion portion disposed in the semiconductor substrate to generate charges according to an amount of received light through photoelectric conversion;
a charge holding portion disposed in the semiconductor substrate to hold charges transferred from the photoelectric conversion portion;
a gate of a transfer transistor disposed on a region of a bottom surface of the semiconductor substrate, the region overlapping the charge holding portion;
a sidewall formed around the gate; and
an in-substrate-shielding portion that is a light-shielding portion disposed in a boundary region of sensor pixels in the semiconductor substrate to extend from a light-receiving surface of the semiconductor substrate toward the bottom surface side, wherein
the in-substrate-shielding portion has a penetrating portion that penetrates the semiconductor substrate, and is in contact with the sidewall at the penetrating portion.
